(19) United States
(12) Patent Application Publication
(10) Pub. No.: US 2020/0106398 A1
(43) Pub. Date: Apr. 2, 2020

(54) Transformer Reconfigurability for Wireless Transceivers

(71) Applicant: Qualcomm Incorporated, San Diego, CA (US)

(72) Inventors: Ahmed Abbas Mohamed Helmy, San Diego, CA (US); Ojas Choksi, San Diego, CA (US); Prakash Thoppay Egambaram, San Diego, CA (US)

(21) Appl. No.: 16/147,005

(22) Filed: Sep. 28, 2018

(51) Int. Cl. H03F 1/32; H04W 92/24; H04W 4/80; H04W 72/04; H03J 9/02

(52) U.S. Cl. CPC H03F 1/3211; H04W 92/24; H03J 2200/10; H04W 72/0453; H03J 9/02; H04W 4/80

(57) ABSTRACT

An apparatus is disclosed including a wireless transceiver implementing transformer reconfigurability. In an example aspect, the apparatus includes a common single-ended node, a common differential node pair, and a transceiver path set. The transceiver path set includes a first transceiver path and a second transceiver path. The first transceiver path comprises a first single-ended interface and a first differential interface and includes a first transformer. The second transceiver path comprises a second single-ended interface and a second differential interface and includes a second transformer. The apparatus also includes single-ended switch circuitry and differential switch circuitry. The single-ended switch circuitry is coupled between each transceiver path of the transceiver path set and the common single-ended node. The differential switch circuitry is coupled between each transceiver path of the transceiver path set and the common differential node pair. Alternatively, an apparatus can include multiple single-ended nodes including first and second single-ended nodes.

### TECHNICAL FIELD

This disclosure relates generally to wireless communications with electronic devices and, more specifically, to implementing multiple transformers that can be reconfigured for extended broadband tunability as part of a wireless transceiver.

### BACKGROUND

Electronic devices include traditional computing devices such as desktop computers, notebook computers, smartphones, wearable devices like a smartwatch, internet servers, and so forth. However, electronic devices also include other types of computing devices such as personal voice assistants, thermostats, automotive electronics, robotics, devices embedded in other machines like refrigerators and industrial tools, Internet of Things (IoT) devices, and so forth. These various electronic devices provide services relating to productivity, remote communication, social interaction, security, safety, entertainment, transportation, and information dissemination. Thus, electronic devices play crucial roles in many aspects of modern society.

Many of the services provided by electronic devices in today's interconnected world depend at least partly on electronic communications. Electronic communications include, for example, those exchanged between or among different electronic devices using wireless or wired signals that are transmitted over one or more networks, such as the Internet or a cellular network. Electronic communications therefore include both wireless and wired transmissions and receptions. To make such electronic communications, an electronic device uses a transceiver, such as a wireless transceiver.

Electronic communications can therefore be realized by propagating signals between two wireless transceivers at two different electronic devices. For example, using a wireless transmitter, a smart phone can transmit a wireless signal to a base station over an air medium as part of an uplink communication to support mobile services. Using a wireless receiver, the smart phone can receive a wireless signal from the base station via the air medium as part of a downlink communication to enable mobile services. With a smart phone, mobile services can include phone and video calls, social media interactions, messaging, watching movies, sharing videos, performing searches, acquiring map information or navigational instructions, locating friends, transferring money, obtaining another service like a car ride, and so forth.

To provide these types of services, electronic devices typically use a wireless transceiver to communicate wireless signals in accordance with some wireless standard. Examples of wireless standards include an IEEE 802.11 Wi-Fi standard and a Fourth Generation (4G) cellular standard, both of which we use today with smartphones and other connected devices. However, efforts to enable a Fifth Generation (5G) wireless standard are ongoing. Next-generation 5G wireless networks are expected to offer significantly higher bandwidths, lower latencies, and access to additional electromagnetic spectrum. Taken together, this means that exciting new wireless services can be provided to users, such as driverless vehicles, augmented reality (AR) and other mixed reality (MR) imaging, on-the-go 4K video streaming, ubiquitous sensors to keep people safe and to use natural resources more efficiently, real-time language translations, and so forth.

To spread these new 5G technologies more widely, many wireless devices in addition to smart phones will be deployed, which is often called the “Internet of Things” (IoT). Compared to today's use of wireless devices, tens of billions, and eventually trillions, of more devices are expected to be connected to the internet with the arrival of the Internet of Things. These IoT devices may include small, inexpensive, and low-powered devices, like sensors and tracking tags. Further, to enable next-generation wireless technologies, 5G wireless devices will be communicating with signals that use wider frequency ranges and that span bands located at higher frequencies of the electromagnetic spectrum. As described above, many of these wireless devices—including smart phones and IoT devices—will be expected to be small, to be inexpensive, to consume less power, or some combination thereof.

Thus, the components that enable wireless communications under these constraints will likewise be expected to be tiny, low cost, and capable of functioning with less energy use. One component that facilitates electronic communications is the wireless transceiver. Unfortunately, the wireless transceivers designed for devices that operate in accordance with the 4G wireless cellular standard of today are not adequate to handle the higher frequencies and more-stringent technical and fiscal demands of the 5G-capable devices of tomorrow.

Consequently, to facilitate the adoption of 5G technologies and the widespread deployment of wireless devices that can provide new capabilities and services, existing wireless transceivers will be replaced with those having superior designs that occupy less space or consume less power while still handling the higher frequencies of 5G networks. Electrical engineers and other designers of electronic devices are therefore striving to develop new wireless transceivers that will enable the promise of 5G technologies to become a reality.

### SUMMARY

An electronic device having a wireless transceiver with reconfigurable transformers is disclosed herein. Example implementations of the disclosed transformer reconfigurability include differential switch circuitry coupled to a set of transformers so that an inductor at a differential side of a first transformer can be coupled in parallel with an inductor at a differential side of a second transformer to extend a tuning range or bandwidth of the second transformer. This reconfigurability can enable one or more transformers to be omitted from a wireless transceiver, which both saves space and reduces a cost of an electronic device. Alternatively, this transformer reconfigurability can enable a wider tunable frequency range with a same number of transformers, which increases the signaling capabilities of a wireless transceiver without increasing the cost of the electronic device.

In an example aspect, an apparatus for transformer reconfigurability is disclosed. The apparatus includes a common single-ended node, a common differential node pair, and a transceiver path set. The transceiver path set includes a first transceiver path and a second transceiver path. The first transceiver path comprises a first single-ended interface and a first differential interface, with the first transceiver path including a first transformer. The second transceiver path comprises a second single-ended interface and a second differential interface, with the second transceiver path including a second transformer. The apparatus also includes single-ended switch circuitry and differential switch circuitry. The single-ended switch circuitry is coupled between each transceiver path of the transceiver path set and the common single-ended node. The differential switch circuitry is coupled between each transceiver path of the transceiver path set and the common differential node pair.

In an example aspect, a system for transformer reconfigurability is disclosed. The system includes a common single-ended node, a common differential node pair, and a transceiver path set. The transceiver path set includes a first transceiver path and a second transceiver path. The first transceiver path comprises a first single-ended interface and a first differential interface, with the first transceiver path including a first transformer. The second transceiver path comprises a second single-ended interface and a second differential interface, with the second transceiver path including a second transformer. The system also includes single-ended switch circuitry coupled between each transceiver path of the transceiver path set and the common single-ended node. The system further includes switch means for selectively coupling each transceiver path of the transceiver path set to another transceiver path via the common differential node pair. Example implementations may further include control means for connecting a differential side of the first transformer to a differential side of the second transformer using the switch means responsive to a frequency of a signal being processed by a wireless transceiver.

In an example aspect, a method for operating a wireless transceiver with transformer reconfigurability is disclosed. The method includes, responsive to a first signal being associated with a first frequency band, routing the first signal associated with the first frequency band from a common single-ended node to a common differential node pair over a first transceiver path via a first transformer having a single-ended side and a differential side. The method also includes, responsive to a second signal being associated with a second frequency band, routing the second signal associated with the second frequency band and engaging the first transceiver path to support the second signal. Specifically, the routing of the second signal includes routing the second signal associated with the second frequency band from the common single-ended node to the common differential node pair over a second transceiver path via a second transformer having a single-ended side and a differential side. Additionally, the engaging of the first transceiver path to support the second signal includes connecting the differential side of the first transformer to the differential side of the second transformer.

In an example aspect, an apparatus for transformer reconfigurability is disclosed. The apparatus includes multiple single-ended nodes, a common differential node pair, and a transceiver path set. The multiple single-ended nodes include a first single-ended node and a second single-ended node. The transceiver path set includes a first transceiver path and a second transceiver path. The first transceiver path comprises a first single-ended interface coupled to the first single-ended node and a first differential interface coupled to the common differential node pair. The first transceiver path includes a first transformer. The second transceiver path comprises a second single-ended interface coupled to the second single-ended node and a second differential interface coupled to the common differential node pair. The second transceiver path includes a second transformer. The apparatus also includes differential switch circuitry coupled between the first transformer and the second transformer.

In an example aspect, a system for transformer reconfigurability is disclosed. The system includes multiple single-ended nodes, a common differential node pair, and a transceiver path set. The multiple single-ended nodes include a first single-ended node and a second single-ended node. The transceiver path set includes a first transceiver path and a second transceiver path. The first transceiver path comprises a first single-ended interface coupled to the first single-ended node and a first differential interface coupled to the common differential node pair. The first transceiver path includes a first transformer. The second transceiver path comprises a second single-ended interface coupled to the second single-ended node and a second differential interface coupled to the common differential node pair. The second transceiver path includes a second transformer. The system further includes switch means for selectively coupling the first transformer to the second transformer. Example implementations may further include control means for connecting a differential side of the first transformer to a differential side of the second transformer using the switch means responsive to a frequency of a signal being processed by a wireless transceiver.

In an example aspect, a method for operating a wireless transceiver with transformer reconfigurability is disclosed. The method includes, responsive to a first signal being associated with a first frequency band, routing the first signal associated with the first frequency band from a first single-ended node to a common differential node pair over a first transceiver path via a first transformer having a single-ended side and a differential side. The method also includes, responsive to a second signal being associated with a second frequency band, routing the second signal associated with the second frequency band and engaging the first transceiver path to support the second signal. Specifically, the routing of the second signal includes routing the second signal associated with the second frequency band from a second single-ended node to the common differential node pair over a second transceiver path via a second transformer having a single-ended side and a differential side. Additionally, the engaging of the first transceiver path to support the second signal includes connecting the differential side of the first transformer to the differential side of the second transformer.

### BRIEF DESCRIPTION OF DRAWINGS

FIG. 1 illustrates an example environment that includes an electronic device in which a wireless transceiver with transformer reconfigurability can be implemented.

FIG. 2 illustrates an example wireless transceiver having at least one set of transformers that includes multiple transformers that can be reconfigured using differential switch circuitry.

FIG. 3 is a schematic diagram illustrating an example wireless transceiver portion with a transceiver path set including a set of transformers and differential switch circuitry for transformer reconfigurability.

FIG. 4 is a flow diagram illustrating an example technique for operating a wireless transceiver with transformer reconfigurability.

FIG. 5 is a schematic diagram of a wireless transceiver portion in accordance with a first example implementation that includes a set of transformers in a narrowband section.

FIGS. 6-1 and 6-2 are a circuit diagrams illustrating an example wireless transceiver portion in accordance with the first example implementation of FIG. 5.

FIGS. 7-1, 7-2, and 7-3 are circuit diagrams of the wireless transceiver portion of FIG. 6-1 or 6-2 with certain switches in associated example switch states for a first, second, and third frequency band, respectively.

FIG. 8 is a schematic diagram of a wireless transceiver portion in accordance with a second example implementation that includes a set of singled-ended amplifiers, a set of transformers, and a set of mixers in a narrowband section.

FIG. 9 is a circuit diagram illustrating an example wireless transceiver portion in accordance with the second example implementation of FIG. 8.

FIGS. 10-1, 10-2, and 10-3 are circuit diagrams of the wireless transceiver portion of FIG. 9 with certain switches in associated example switch states for a first, second, and third frequency band, respectively.

FIG. 11 is a circuit diagram that depicts and an example segregated capacitor bank that can be substituted for an adjustable tuning capacitor of a transistor and a switch pair of differential switch circuitry.

FIG. 12 is a flow diagram illustrating an example process for operating a wireless transceiver with transformer reconfigurability in accordance with the first implementation.

FIG. 13 is a flow diagram illustrating another example process for operating a wireless transceiver with transformer reconfigurability in accordance with the second implementation.

### DETAILED DESCRIPTION

To provide today's mobile services, many electronic devices communicate via wireless signals using a wireless transceiver. A wireless transceiver can transmit or receive a wireless signal and includes a transmit chain or a receive chain (or both). Each transmit chain or receive chain may include at least one transformer that has a first side for a primary “coil” (e.g., a primary inductor) and a second side for a secondary “coil” (e.g., a secondary inductor), with each “coil” implemented with at least one inductor. A transformer can process or condition a signal that is propagating through a transmit or receive chain in different manners. For example, a transformer can change a voltage level of a signal that is propagated from the first side to the second side (e.g., from the primary inductor to the secondary inductor) or can isolate two portions of a circuit. Additionally, a transformer can be combined with a capacitive component to create an inductor-capacitor tank that is used to tune the propagating signal. Further, a transformer can convert the propagating signal from having a single-ended (SE) format as a single-ended signal to having a differential format as a differential signal, or vice versa. In such cases, a transformer of a wireless transceiver can include a single-ended side and a differential side.

Wireless transceivers, including those that incorporate one or more transformers, can be designed to support wideband wireless communications, such as those for 5th-Generation (5G) or 5G New Radio (NR) wireless systems. To enable signals to be transceived across a wide frequency range, some electronic devices use multiple transceivers. In an example receiving scenario, an overall receiver may be constructed from multiple narrowband receivers. Each narrowband receiver includes components that are designed for a specific, relatively-narrow frequency range portion of an overall wide frequency range. Each respective narrowband receiver may, for instance, utilize a respective filter that is designed to achieve certain performance specifications for the corresponding respective narrow frequency range. Because each of the multiple narrowband receivers utilize respective bandwidth-specific components, such as bandwidth-specific mixers or amplifiers, the bandwidth-specific components are duplicated in multiple instances at multiple narrowband receivers across the overall wideband receiver. Consequently, the use of multiple narrowband receivers increases the area and cost of receiver circuitry deployed in electronic devices. The situation is analogous with wideband transmitter circuitry that employs multiple narrowband transmitters and results in a similar financial and area penalty.

To reduce the number of components included in transceiver circuitry, while continuing to cover a wide frequency band, wideband components can be employed in lieu of duplicative narrowband components. Such wideband components can be employed in a receive chain or a transmit chain of a transceiver. Thus, a straightforward approach involves replacing all of one type of narrowband component across multiple transceiver paths in a transmit or receive chain with a corresponding broadband component of the same type. For example, a set of narrowband filters can be replaced with a single broadband filter, and this replacement may be repeated for each type of component (e.g., amplifiers and mixers). However, certain components, like transformers, cannot be manufactured to individually cover a wide frequency band. Consequently, creating a compact broadband implementation imposes challenges in the design of the transceiver, especially for passive electromagnetic elements such as transformers and individual inductors, which are more difficult to shrink as compared to active components that are formed from transistors.

In contrast with the straightforward approach described above, hybrid implementations described herein entail replacing some sets of narrowband components with a reduced number, or even a single, broadband component while one or more other sets of narrowband components are not replaced. Thus, within a given transmit or receive chain, some functions are implemented using multiple narrowband components, and other functions are implemented using as few as a single broadband component. To do so, a transceiver path set includes at least one section with one or more shared broadband components and at least one other section with a separate narrowband component (e.g., a transformer) for each transceiver path.

In an example broadband transceiver approach, a set of transformers is used to handle a broadband frequency range, with the set including multiple narrowband transformers that are distributed across multiple transceiver paths of a transceiver path set. For instance, three transformers can be stacked in parallel. Each such transformer can have a fixed turns ratio between the “coils” (e.g., between primary and secondary inductors, respectively, for a receiver implementation). A respective transformer can cover a respective narrowband frequency range of an overall broadband frequency range. For instance, a first, a second, and a third transformer can respectively correspond to a first frequency range, a second frequency range, and a third frequency range (e.g., a low-band, a mid-band, and a high-band frequency range). Any transformer can be selectively and independently activated to process a signal having a frequency within a respective corresponding frequency range (e.g., an assigned frequency band).

Implementing different transceiver paths with different respective transformers and various combinations of narrowband versus broadband components can facilitate the realization of a wireless transceiver that is capable of handling a broadband frequency range, such as those for 5G-certified electronic devices. Some plans for 5G standards or systems anticipate that wireless transceivers will be able to process wireless signals having a wide frequency range—e.g., from 600 megahertz (MHz) to 6 gigahertz (GHz). Thus, for commercially-viable hardware, transceiver tunability between 0.6 to 6.0 GHz has to be provided while the transceiver also achieves other metrics in terms of area, power consumption, and performance. As noted above, realizing a compact broadband implementation imposes challenges in the design of a wireless transceiver, especially with the passive electromagnetic elements—e.g., inductors and transformers. In other words, each individual transformer occupies some area within an electronic device, which is costly and adversely impacts industry efforts to create smaller form factors for portable electronic devices. This is especially pertinent because as the sizes of active components that are formed from transistors continue to decrease, the relative sizes of passive inductors and transformers appreciably increase and can dominate a physical area of a transceiver.

To address this disparity between sizes of active components versus sizes of passive components, as well as to enable a more compact broadband wireless transceiver to be realized, a tunable range of individual transformers of a set of transformers can be extended as described herein. The narrowband tunable range of a given transformer is extended without adding an inductor to the design. Consequently, an overall wideband tunable frequency range for a set of transformers for a broadband wireless transceiver is increased without adding another transformer. This can reduce a size of the wireless transceiver while still meeting 5G broadband specifications. Typically, a transformer is designed to operate over some corresponding frequency range. If three transformers are incorporated into a transceiver chain, the broadband coverage is therefore the unity of the three respective corresponding frequency ranges. Application of the techniques described herein, however, increases individual corresponding frequency ranges of individual transformers and their transceiver paths to thereby increase the overall broadband frequency range of the wireless transceiver.

Typically, the inductive value of a given side of a transformer affects a self-resonant frequency (SRF) of the transformer. The SRF can bound an upper frequency range for which a transformer can operate. Generally, increasing the SRF increases the upper frequency bound for operation of the transformer. The SRF of the transformer can be increased by decreasing the inductive value of the given side of the transformer. The inductive value can be decreased by coupling an additional inductor in parallel with the given side of the transformer. A separate additional inductor, however, would consume a significant area of the wireless transceiver.

Instead of adding an additional inductor, example implementations that are described herein loan or reuse an inductor from another transformer of a wireless transceiver. The wireless transceiver includes a set of transceiver paths with each path respectively corresponding to a frequency band of multiple frequency bands. Each transceiver path has a respective transformer coupled in parallel with the other transformers with regard to a signal processing path. In operation, an inductor from a first transformer of a first transceiver path is selectively coupled in parallel with another inductor from a second transformer of a second transceiver path responsive to a signal having a frequency within a frequency band corresponding to the second transformer. With the two inductors being coupled together in parallel, the resulting inductive value of the second transformer is decreased. This decreased inductive value increases the SRF of the second transformer and thereby increases the applicable narrowband frequency coverage of the second inductor without introducing another transformer or adding another separate inductor.

Generally, multiple narrowband transformers are respectively distributed across a set of transceiver paths. Other components can also be implemented as separate multiple narrowband components per transceiver path or as a shared broadband component for the multiple transceiver paths of the set. The inductors of different transformers can be coupled together in parallel using switching circuitry to engage the inductor reuse. In a first example implementation, the multiple narrowband transformers are coupled in parallel with respect to each other and between two broadband amplifiers. The switching circuitry is therefore also used to activate a given narrowband transformer for a signal associated with a corresponding frequency band. In a second example implementation, respective ones of the multiple narrowband transformers are coupled between respective narrowband amplifiers and narrowband mixers in each respective transceiver path of the set of transceiver paths. Here, the switching circuitry is used to selectively engage inductors for reuse by another narrowband transformer. The other narrowband components can be activated or deactivated to activate the respective transceiver path for signaling processing responsive to a frequency of the signal to be processed.

In these manners, an inductor of a first transformer can be “loaned” to lower an inductive value of a second transformer. This lowered inductive value increases the SRF of the second transformer, which extends the higher frequencies of signals that the second transformer can process. Accordingly, the overall wideband frequency range of the overall wireless transceiver is likewise increased. Either of the two implementations explicitly described above can include other broadband or narrowband components disposed anywhere along any of the transceiver paths. Additionally, other circuit arrangements and combinations of components can alternatively be implemented to realize a wireless transceiver with transformer reconfigurability.

Further, some implementations can include a segregated capacitor bank coupled in parallel with an inductor of one or more narrowband transformers. The segregated capacitor bank includes a main capacitor bank an auxiliary capacitor bank. The auxiliary capacitor bank is activated for lower frequencies. By disconnecting the auxiliary capacitor bank for higher frequencies, undesirable parasitic capacitance is substantially prevented from affecting the upper frequency range of a given transformer. Thus, the given transformer can better handle both lower and upper frequencies to thereby extend a corresponding tuning range of the given transformer.

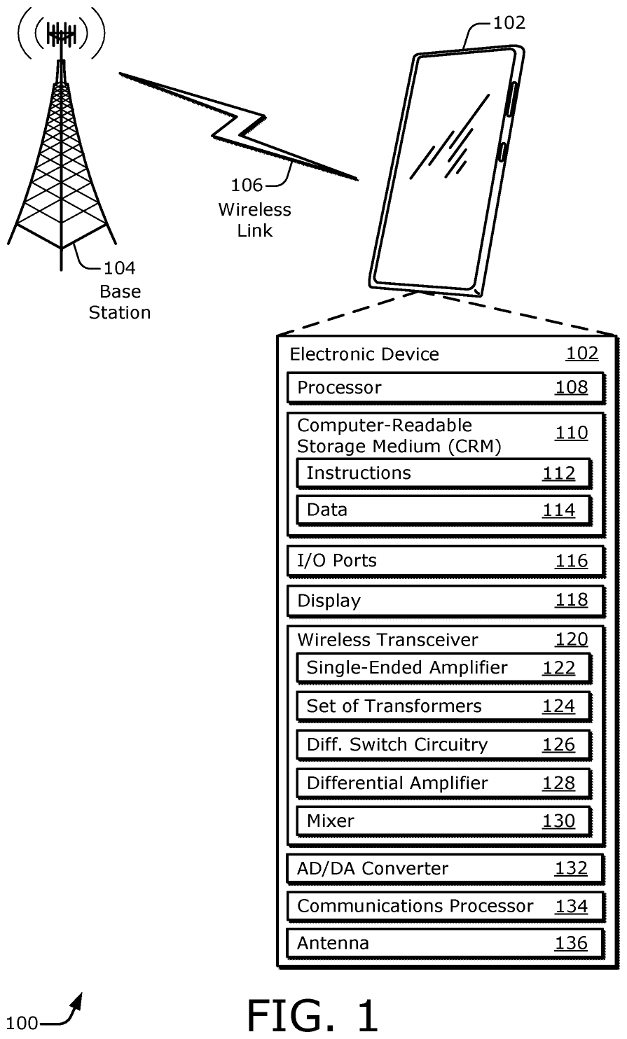

FIG. 1 illustrates an example environment 100 that includes an electronic device 102 with a wireless transceiver 120 in which transformer reconfigurability can be implemented. In the environment 100, the electronic device 102 communicates with a base station 104 through a wireless link 106. As shown, the electronic device 102 is depicted as a smart phone. However, the electronic device 102 may be implemented as any suitable computing or other electronic device, such as a cellular base station, broadband router, access point, cellular or mobile phone, gaming device, navigation device, media device, laptop computer, desktop computer, tablet computer, server computer, network-attached storage (NAS) device, smart appliance, vehicle-based communication system, Internet of Things (IoT) device, sensor or security device, asset tracker, fitness management device, wearable device such as intelligent glasses or smart watch, and so forth.

The base station 104 communicates with the electronic device 102 via the wireless link 106, which may be implemented as any suitable type of wireless link. Although depicted as a base station tower of a cellular radio network, the base station 104 may represent or be implemented as another device, such as a satellite, terrestrial broadcast tower, access point, peer to peer device, mesh network node, fiber optic line, another electronic device as described above generally, and so forth. Hence, the electronic device 102 may communicate with the base station 104 or another device via a wired connection, a wireless connection, or a combination thereof.

The wireless link 106 extends between the electronic device 102 and the base station 104. The wireless link 106 can include a downlink of data or control information communicated from the base station 104 to the electronic device 102 and an uplink of other data or control information communicated from the electronic device 102 to the base station 104. The wireless link 106 may be implemented using any suitable communication protocol or standard, such as 3rd Generation Partnership Project Long-Term Evolution (3GPP LTE), IEEE 802.11, IEEE 802.16, Bluetooth™, and so forth.

As shown, the electronic device 102 includes a processor 108 and a computer readable storage medium 110 (CRM 110). The processor 108 may include any type of processor, such as an application processor or a multi-core processor, that is configured to execute processor-executable instructions (e.g., code) stored by the CRM 110. The CRM 110 may include any suitable type of data storage media, such as volatile memory (e.g., random access memory (RAM)), non-volatile memory (e.g., Flash memory), optical media, magnetic media (e.g., disk or tape), and so forth. In the context of this disclosure, the CRM 110 is implemented to store instructions 112, data 114, and other information of the electronic device 102, and thus the CRM 110 does not include transitory propagating signals or carrier waves.

The electronic device 102 may also include input/output ports 116 (I/O ports 116) or a display 118. The I/O ports 116 enable data exchanges or interaction with other devices, networks, or users. The I/O ports 116 may include serial ports (e.g., universal serial bus (USB) ports), parallel ports, audio ports, infrared (IR) ports, camera or other sensor ports, and so forth. The display 118 can be realized as a screen or projection that presents graphics provided by the electronic device 102, such as a user interface associated with an operating system, program, or application. Alternatively or additionally, the display 118 may be implemented as a display port or virtual interface through which graphical content of the electronic device 102 is communicated or presented.

For communication purposes, the electronic device 102 also includes at least one wireless transceiver 120, at least one analog-to-digital or digital-to-analog converter 132 (AD/DA converter 132), at least one communications processor 134, and at least one antenna 136. The wireless transceiver 120 provides connectivity to respective networks and other electronic devices connected therewith using radio-frequency (RF) wireless signals. Additionally or alternatively, the electronic device 102 may include a wired transceiver (not shown), such as an Ethernet or fiber optic interface for communicating over a personal or local network, an intranet, or the Internet. The wireless transceiver 120 may facilitate communication over any suitable type of wireless network, such as a wireless local area network (LAN) (WLAN), a peer-to-peer (P2P) network, a mesh network, a cellular network, a wireless wide area network (WWAN), a navigational network (e.g., the Global Positioning System (GPS) of North America or another Global Navigation Satellite System (GNSS)), a wireless personal area network (WPAN), or some combination thereof. In the context of the example environment 100, the wireless transceiver 120 enables the electronic device 102 to communicate with the base station 104 and networks connected therewith. However, the wireless transceiver 120 can enable the electronic device 102 to communicate directly with other devices or using alternative wireless networks.

The wireless transceiver 120 includes circuitry, logic, or other hardware for transmitting or receiving a wireless signal for at least one communication frequency band. For example, the wireless transceiver 120 can implement at least one, e.g., radio frequency (RF) transceiver to process data and/or signals associated with communicating data of the electronic device 102 via the antenna 136. The AD/DA converter 132 can be coupled between the wireless transceiver 120 and the communications processor 134. The AD/DA converter 132 performs analog-to-digital conversion (ADC) or digital-to-analog conversion (DAC) for downlink signals or uplink signals, respectively, to facilitate communication between the wireless transceiver 120 and the communications processor 134. The wireless transceiver 120 may be associated with, or may include, the communications processor 134. The communications processor 134, such as a baseband modem, may be implemented as a system on-chip (SoC) that provides a digital communication interface for data, voice, messaging, and other applications of the electronic device 102.

Accordingly, the communications processor 134 may include baseband circuitry to perform high-rate sampling processes that can include analog-to-digital conversion (ADC), digital-to-analog conversion (DAC), gain correction, skew correction, frequency translation, and so forth. The communications processor 134 may also include logic to perform in-phase/quadrature (I/Q) operations, such as synthesis, encoding, modulation, demodulation, and decoding. A communications processor 134 may generally be realized as a modem, as a digital signal processor (DSP), or as a communications-oriented processing unit that is configured to perform signal processing to support communications via one or more networks. Alternatively, ADC or DAC operations may be performed by a separate component, such as the AD/DA converter 132.

Generally, the wireless transceiver 120 can include filters, switches, amplifiers, mixers, and so forth for routing and conditioning signals that are transmitted or received via the antenna 136. As shown, the wireless transceiver 120 includes at least one single-ended amplifier 122, at least one set of transformers 124, differential switch circuitry 126, at least one differential amplifier 128, and at least one mixer 130. In some implementations, the single-ended amplifier 122, which amplifies a strength of a signal, is coupled to the antenna 136. Thus, the single-ended amplifier 122 can couple a wireless signal between the antenna 136 and the set of transformers 124, in addition to increasing a strength of the signal. The set of transformers 124 includes multiple individual transformers distributed across a set of transceiver paths (not shown in FIG. 1). In some implementations, the differential switch circuitry 126 can switchably couple individual transformers of the set of transformers 124 to each other or to the differential amplifier 128. The set of transformers 124 can provide a physical or electrical separation between the single-ended amplifier 122 and other circuitry of the wireless transceiver 120, such as the differential amplifier 128 or the mixer 130, as the set of transformers 124 couples a signal to the other circuitry. The set of transformers 124, as part of multiple transceiver paths, also conditions a signal propagating through the wireless transceiver 120.

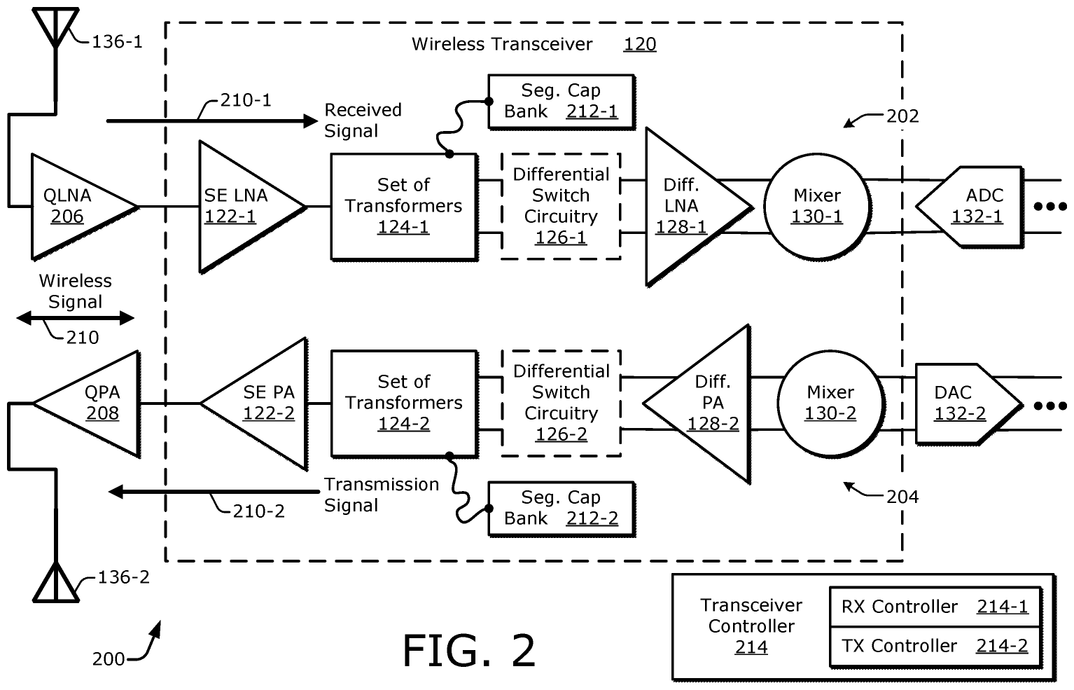

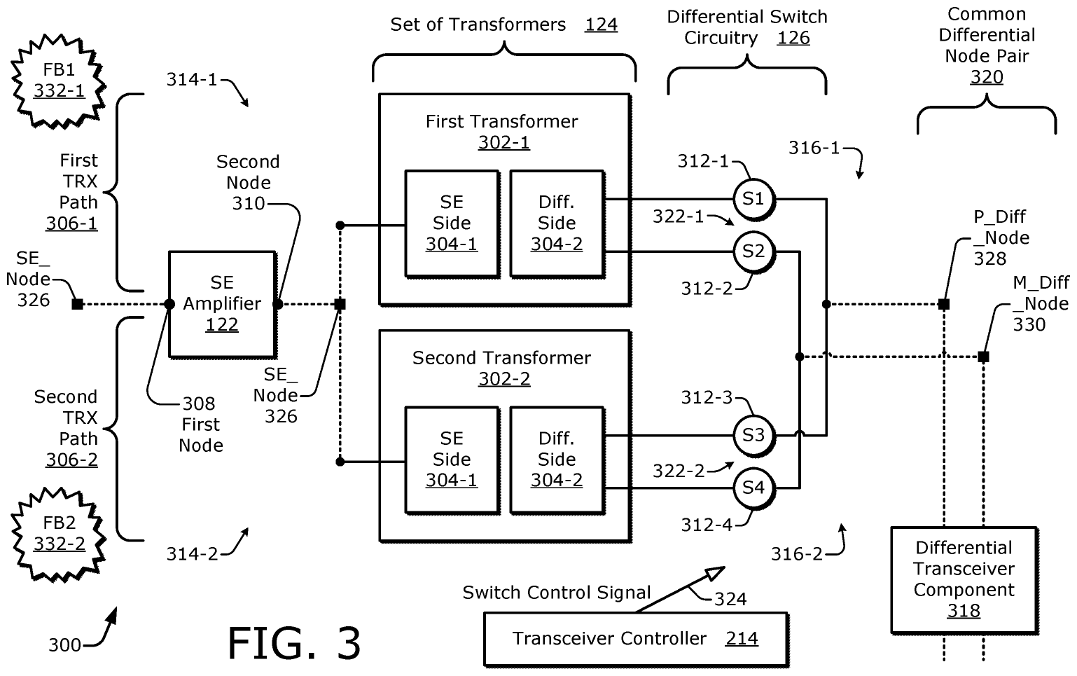

The differential amplifier 128, like the single-ended amplifier 122, reinforces a strength of a signal propagating through the wireless transceiver 120. The wireless transceiver 120 can further perform frequency conversion using a synthesized signal and the mixer 130. The mixer 130 may include an upconverter and/or a downconverter that performs frequency conversion in a single conversion step, or through multiple conversion steps. The wireless transceiver 120 may also include logic (not shown) to perform in-phase/quadrature (I/Q) operations, such as synthesis, encoding, modulation, demodulation, and decoding using a synthesized signal. In some cases, components of the wireless transceiver 120 are implemented as at least partially separate receiver and transmitter entities. Additionally or alternatively, the wireless transceiver 120 can be realized using multiple or different sections to implement respective receiving and transmitting operations (e.g., using separate transmit and receive chains). Example operations of, as well as interactions between, the illustrated components of the wireless transceiver 120 are described below with reference to FIG. 2.

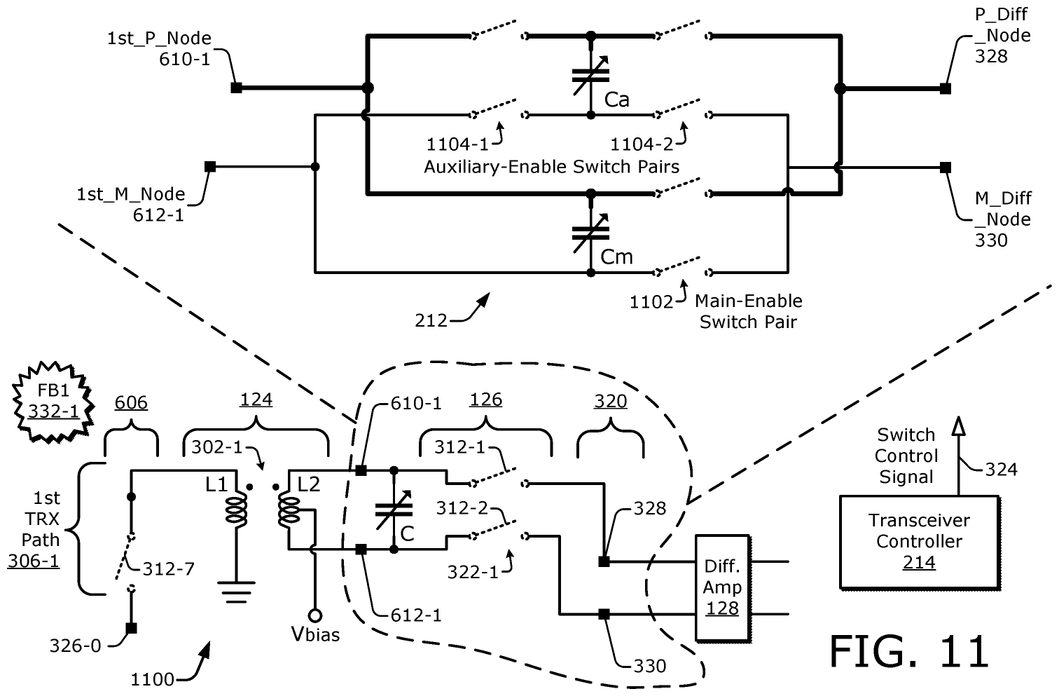

The description of FIG. 3 provides examples of a transceiver path set having multiple transceiver paths including the differential switch circuitry 126 and multiple respective transformers that realize the set of transformers 124. FIGS. 5 to 7-3 pertain to example implementations with a common single-ended node and in which the set of transformers 124 is part of a narrowband section with multiple narrowband components. FIGS. 8 to 10-3 pertain to example implementations with multiple single-ended nodes and in which the single-ended amplifier 122 or the mixer 130 may also be comprised of multiple narrowband components as part of the narrowband section of a wireless transceiver portion. FIG. 11 pertains to example implementations in which a segregated capacitor bank is implemented in conjunction with at least one transformer of a set of transformers 124. Thus, as described herein, the wireless transceiver 120 can implement transformer reconfigurability for wireless transceivers using at least the set of transformers 124 and the differential switch circuitry 126.

FIG. 2 illustrates generally at 200 an example wireless transceiver 120 including a receive chain 202 and a transmit chain 204 that each have a set of transformers 124 and differential switch circuitry 126 to implement transformer reconfigurability. The example receive chain 202 is depicted in the upper half of the wireless transceiver 120, and the example transmit chain 204 is depicted in the lower half. Each of the receive chain 202 and the transmit chain 204 is coupled to at least one antenna 136 to enable a wireless signal 210 to be received or transmitted, respectively. Thus, the wireless signal 210 can include a received signal 210-1 or a transmission signal 210-2 that is being processed by the wireless transceiver 120. As illustrated, the receive chain 202 is coupled to an antenna 136-1 via a quadrature low-noise amplifier 206 (QLNA 206). The transmit chain 204 is coupled to an antenna 136-2 via a quadrature power amplifier 208 (QPA 208).

Although the receive chain 202 and the transmit chain 204 are shown coupled to two different antennas 136-1 and 136-2, the chains may instead be coupled to multiple antennas, to the same one or more antennas, to at least one antenna array, and so forth. Further, although a particular set of components in a particular order are illustrated in FIG. 2 and described herein, each of the receive chain 202 or the transmit chain 204 may include different components, different combinations of components, different numbers or orders of components, alternative interconnections, and so forth. Additionally, the receive chain 202 and the transmit chain 204 may share one or more components, such as an antenna array, a switch matrix, or a local oscillator (not shown).

In example implementations, the receive chain 202 processes a received signal 210-1 that is obtained via the antenna 136-1 and the quadrature low-noise amplifier 206. The receive chain 202 includes, from left-to-right, a single-ended low-noise amplifier 122-1 (SE LNA 122-1), a set of transformers 124-1, differential switch circuitry 126-1, a differential low-noise amplifier 128-1 (Diff. LNA 128-1), a mixer 130-1, and an analog-to-digital converter 132-1 (ADC 132-1). As indicated by the ellipses (“ . . . ”) depicted on the right of FIG. 2, the receive chain 202 can continue processing the received signal 210-1, e.g., using intermediate frequency (IF) circuitry or baseband circuitry (not explicitly indicated in FIG. 2), such as the communications processor 134 of FIG. 1.

In an example operation, the single-ended low-noise amplifier 122-1 amplifies the received signal 210-1 and provides the amplified received signal 210-1 to the set of transformers 124-1. The set of transformers 124-1 includes two or more transformers. Here, the set of transformers 124-1 provides physical separation between different portions of the wireless transceiver 120 and converts a single-ended received signal 210-1 into a differential (e.g., balanced or double-ended) received signal 210-1. The set of transformers 124-1 can further condition the received signal 210-1, such as by altering a voltage level of the received signal 210-1, tuning the received signal 210-1 (e.g., using an inductor and a capacitor coupled together as an LC tank), and so forth. As shown, each transformer of the set of transformers 124-1 can include or can be associated with a segregated capacitor bank 212-1 (Seg. Cap Bank 212-1). Example implementations for a segregated capacitor bank 212 are described with reference to FIG. 11.

As described below with reference to FIG. 3 et seq., the differential switch circuitry 126-1 can couple individual transformers of the set of transformers 124-1 to each other to change the inductance and therefore a self-resonant frequency (SRF) thereof. By changing the self-resonant frequency of a given transformer, a frequency range thereof can be extended, and an overall frequency range of the set of transformers 124-1 can be broadened without adding another separate transformer or inductor to the receive chain 202. Further, in some implementations, the differential switch circuitry 126-1 can couple one or more transformers of the set of transformers 124-1 to the differential low-noise amplifier 128-1. This implementation variability is represented by the dashed lines around the differential switch circuitry 126-1.

Thus, the set of transformers 124-1 passes the conditioned, differential received signal 210-1 from at least one transformer thereof to the differential low-noise amplifier 128-1 to be amplified. After the differential low-noise amplifier 128-1 increases a signal strength of the received signal 210-1, the mixer 130-1 mixes a reference signal produced by a local oscillator (not shown) with the amplified received signal 210-1 to down-convert the received signal 210-1 from one frequency to a lower frequency, such as from a radio frequency (RF) to an intermediate frequency (IF) or from an intermediate frequency to a baseband (BB) frequency (or directly from RF to BB frequency). The down-converted received signal 210-1 is passed out of the wireless transceiver 120 to the analog-to-digital converter 132-1, which converts the analog information encoded in the received signal 210-1 into digital information. The analog-to-digital converter 132-1 can then forward the received signal 210-1 in a digital format to additional IF or BB components for further processing.

In example implementations, the transmit chain 204 operates in a manner that is analogous to that of the receive chain 202, but in an opposite direction and on a transmission signal 210-2. The transmit chain 204 includes, from right-to-left, a digital-to-analog converter 132-2 (DAC 132-2), a mixer 130-2, a differential power amplifier 128-2 (Diff. PA 128-2), differential switch circuitry 126-2, a set of transformers 124-2, and a single-ended power amplifier 122-2 (SE PA 122-2). In operation, the digital-to-analog converter 132-2 receives a digital version of the transmission signal 210-2 from baseband circuitry, such as from the communications processor 134 of FIG. 1, and converts the transmission signal 210-2 to an analog version thereof. The mixer 130-2 upconverts the analog transmission signal 210-2, and the differential power amplifier 128-2 amplifies the upconverted transmission signal 210-2 to produce an amplified transmission signal 210-2.

The differential power amplifier 128-2 applies the amplified transmission signal 210-2 in a differential mode to the set of transformers 124-2. The set of transformers 124-2 includes two or more transformers. The set of transformers 124-2 converts the transmission signal 210-2 from the differential mode to a single-ended mode and can also condition the transmission signal 210-2. As shown, each transformer of the set of transformers 124-2 can include or can be associated with a segregated capacitor bank 212-2 (Seg. Cap Bank 212-2). Example implementations for a segregated capacitor bank 212 are described with reference to FIG. 11. The set of transformers 124-2 provides the conditioned, single-ended transmission signal 210-2 to the single-ended power amplifier 122-2. After amplification, the single-ended power amplifier 122-2 provides an amplified transmission signal 210-2 to the quadrature power amplifier 208 for subsequent electromagnetic emanation from the antenna 136-2.

As described below with reference to FIG. 3 et seq., the differential switch circuitry 126-2 can couple individual transformers of the set of transformers 124-2 to each other to change a self-resonant frequency (SRF) thereof. By changing the self-resonant frequency of a given transformer, a frequency range thereof can be extended, and an overall frequency range of the set of transformers 124-2 can be broadened without adding another separate transformer or inductor to the transmit chain 204. Further, in some implementations, the differential switch circuitry 126-2 can couple the differential power amplifier 128-2 to one or more transformers of the set of transformers 124-2. This implementation variability is represented by the dashed lines around the differential switch circuitry 126-2.

Operation of the wireless transceiver 120 can be at least partially controlled by a transceiver controller 214. The communications processor 134 of FIG. 1, for example, can include the transceiver controller 214. As shown, the transceiver controller 214 includes a receiver controller 214-1 (RX Controller 214-1) and a transmitter controller 214-2 (TX Controller 214-2). The receiver controller 214-1 controls operation of the receive chain 202, and the transmitter controller 214-2 controls operation of the transmit chain 204. Thus, the receiver controller 214-1 can control operation of the differential switch circuitry 126-1 to reconfigure transformers of the set of transformers 124-1 to have different self-resonant frequencies. Similarly, the transmitter controller 214-2 can control operation of the differential switch circuitry 126-2 to reconfigure transformers of the set of transformers 124-2 to have different self-resonant frequencies. Some of the description below focuses on the structure, operation, and control of the differential switch circuitry 126-1, the set of transformers 124-1, and the segregated capacitor bank 212-1 of the receive chain 202. However, the described principles are likewise applicable to the structure, operation, and control of the differential switch circuitry 126-2, the set of transformers 124-2, and the segregated capacitor bank 212-2 of the transmit chain 204.

FIG. 3 is a schematic diagram illustrating an example transceiver path set 300 including differential switch circuitry 126 and multiple transceiver paths, each of which includes at least one transformer 302 of a set of transformers 124. The schematic diagram also depicts the transceiver controller 214. The set of transformers 124 is distributed across the transceiver path set 300. The set of transformers 124 includes multiple transformers and has a quantity of two transformers in this example: a first transformer 302-1 and a second transformer 302-2. Each transformer 302 includes a single-ended side 304-1 (SE Side 304-1) and a differential side 304-2 (Diff. Side 304-2). Also shown as part of the transceiver path set 300 is at least one single-ended amplifier 122 and at least one differential transceiver component 318.

As illustrated in FIG. 3, the transceiver path set 300 includes two transceiver paths: a first transceiver path 306-1 (First TRX Path 306-1) and a second transceiver path 306-2 (Second TRX Path 306-2). However, a transceiver path set 300 can include more than two transceiver paths. Each respective transceiver path 306 includes a respective single-ended interface 314 and a respective differential interface 316. As shown, the first transceiver path 306-1 includes a first single-ended interface 314-1 and a first differential interface 316-1. The first transceiver path 306-1 also includes the first transformer 302-1. The second transceiver path 306-2 includes a second single-ended interface 314-2 and a second differential interface 316-2. The second transceiver path 306-2 also includes the second transformer 302-2.

In example implementations, each respective transceiver path 306 corresponds to at least one respective frequency band 332 of multiple frequency bands and is therefore designed to process signals within the corresponding frequency band 332. Thus, the first transceiver path 306-1 corresponds to a first frequency band 332-1 (FB1 332-1), and the second transceiver path 306-2 corresponds to a second frequency band 332-2 (FB2 332-2). Each associated respective transformer 302 can therefore correspond to the respective frequency band 332. As shown, the first transceiver path 306-1 includes the first transformer 302-1 having two sides 304: a single-ended side 304-1 and a differential side 304-2. The second transceiver path 306-2 includes the second transformer 302-2 also having two sides 304: a single-ended side 304-1 and a differential side 304-2.

Each side 304 of a transformer 302 can include at least one inductor, which inductors are explicitly shown in, e.g., FIGS. 6-1 and 9. Each transformer 302 includes a single-ended interface at the single-ended side 304-1 thereof and a differential interface at the differential side 304-2 thereof. The first transformer 302-1 is coupled between the first single-ended interface 314-1 and the first differential interface 316-1 of the first transceiver path 306-1. The first transformer 302-1 is configured as a first balun to convert between a single-ended signaling format and a differential signaling format, in either direction. The second transformer 302-2 is coupled between the second single-ended interface 314-2 and the second differential interface 316-2 of the second transceiver path 306-2. The second transformer 302-2 is configured as a second balun to convert between the single-ended signaling format and the differential signaling format, in either direction.

As illustrated, the differential switch circuitry 126 for two transceiver paths includes two switch pairs and four switches. The two switch pairs include a first switch pair 322-1 associated with the first transformer 302-1 and a second switch pair 322-2 associated with the second transformer 302-2. The first switch pair 322-1 includes a first switch 312-1 (S1) and a second switch 312-2 (S2). The second switch pair 322-2 includes a third switch 312-3 (S3) and a fourth switch 312-4 (S4). The terms “first,” “second,” and so forth are provided to distinguish similar or analogous items from one another within a given context—such as a particular implementation, a single drawing figure, or a claim. However, a first item in one context may therefore differ from a first item in another context.

In example operations, the transceiver controller 214 generates a switch control signal 324. The switch control signal 324 controls a switch state of each switch 312. Each switch 312 can be in an open state or a closed state. Each switch 312 can be implemented using, for example, a transistor that is turned on and permitting current to flow for the closed switch state and that is turned off and preventing current from flowing for the open switch state. A transistor can be realized using, for instance, a metal-oxide-semiconductor (MOS) field-effect transistor (FET), or MOSFET. In these instances, the switch control signal 324 can be coupled to a gate terminal of a MOSFET to bias the transistor into an on state or an off state to close or open a switch, respectively.

In example implementations, each transceiver path 306 extends between two endpoints: at least one single-ended node 326 (SE Node 326) and at least one common differential node pair 320. With two transceiver paths, the first and second transceiver paths 306-1 and 306-2 are coupled in parallel with each other between the single-ended node 326 and the common differential node pair 320. The common differential node pair 320 includes a plus differential node 328 (P Diff Node 328) and a minus differential node 330 (M Diff Node 330). The single-ended node 326 can be located on an antenna side or on a baseband side of a single-ended amplifier 122 along a given transceiver path set 300.

The set of transformers 124 and the differential switch circuitry 126 are coupled together in series between the single-ended node 326 and the common differential node pair 320. Individual transformers of the set of transformers 124 are selectively or switchably coupled to each other via the differential switch circuitry 126. For example, the differential side 304-2 of each transformer 302 can be selectively coupled to at least one other differential side 304-2 of another transformer 302. This enables a differential side 304-2 of one transformer 302 to be coupled in parallel with a differential side 304-2 of another (e.g., activated) transformer 302 to affect the SRF of the activated transformer 302.

As shown, the first switch pair 322-1 is coupled between the differential side 304-2 of the first transformer 302-1 and the common differential node pair 320. More specifically, the first switch 312-1 and the second switch 312-2 are coupled between the differential side 304-2 of the first transformer 302-1 and the plus differential node 328 and the minus differential node 330, respectively. The second switch pair 322-2 is coupled between the differential side 304-2 of the second transformer 302-2 and the common differential node pair 320. More specifically, the third switch 312-3 and the fourth switch 312-4 are coupled between the differential side 304-2 of the second transformer 302-2 and the plus differential node 328 and the minus differential node 330, respectively.

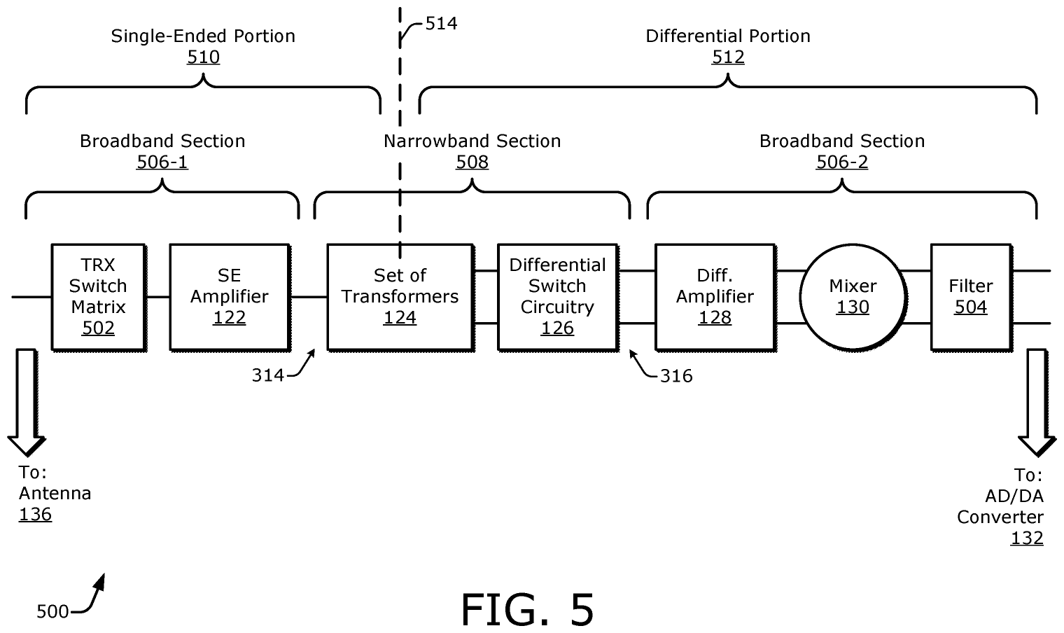

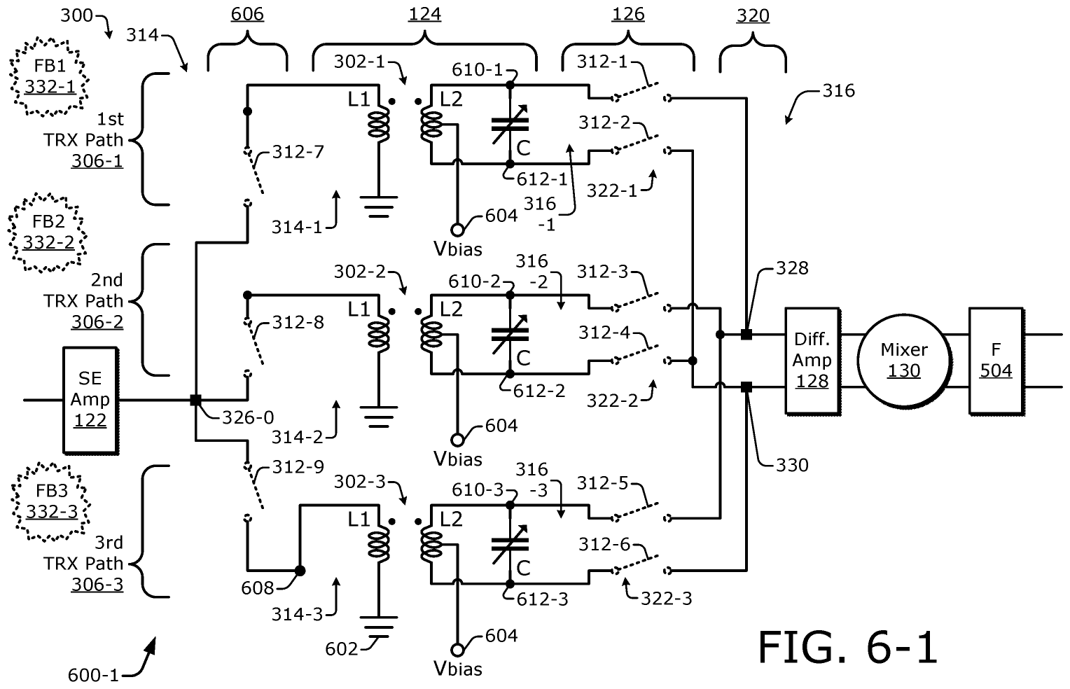

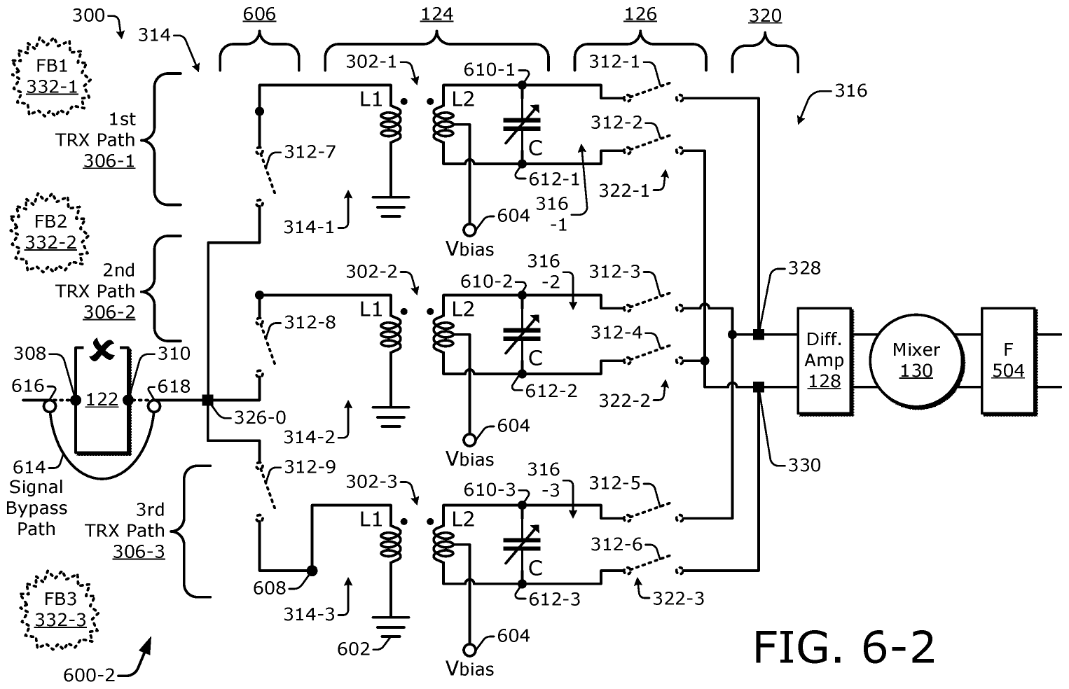

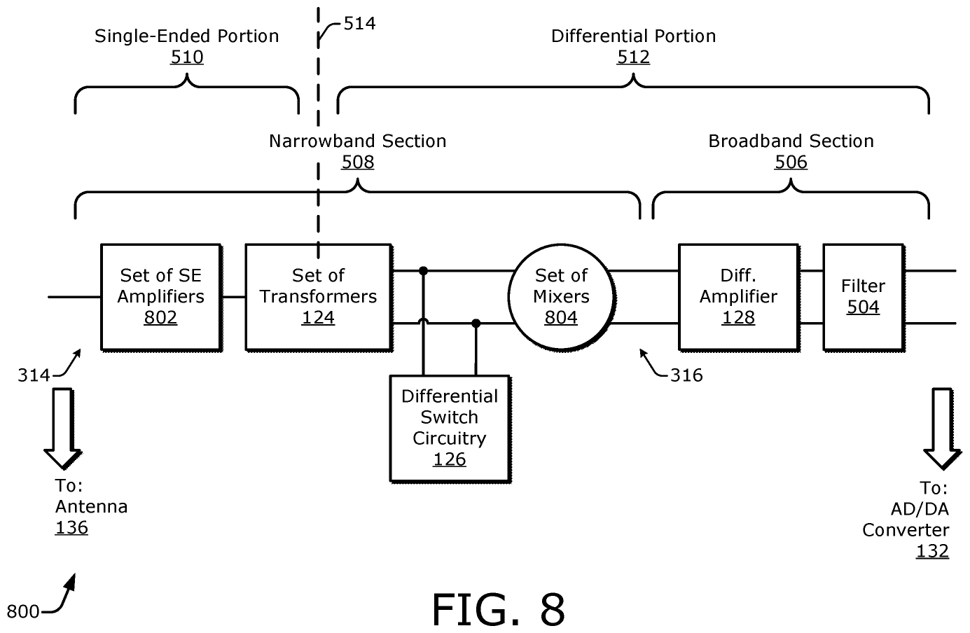

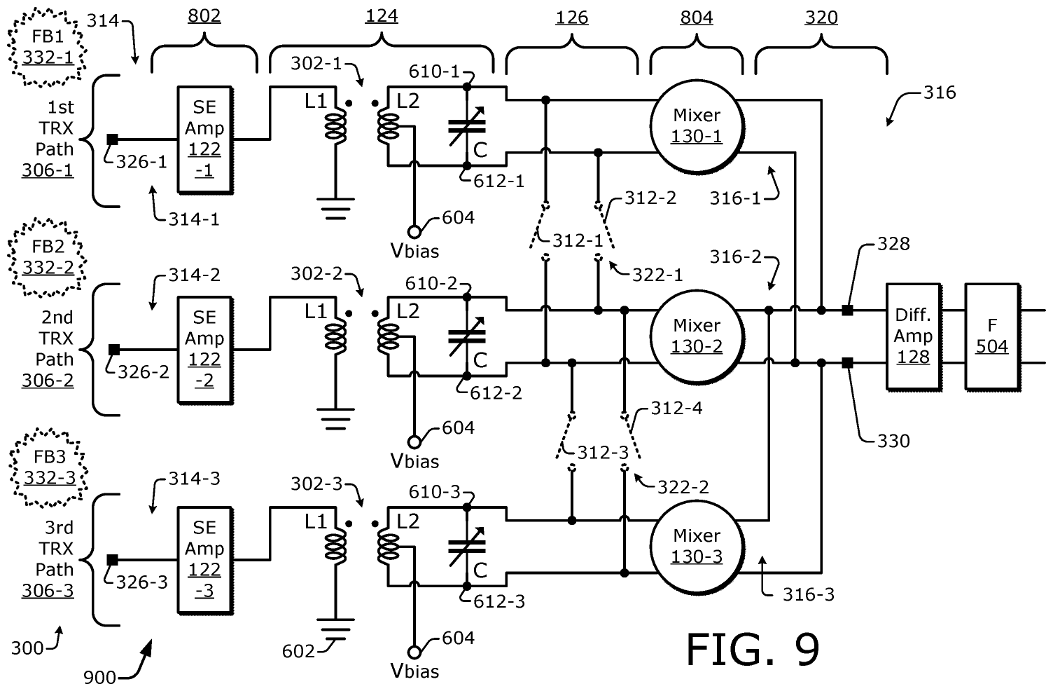

Generally, one or more other components are coupled along each of the first and second transceiver paths 306-1 and 306-2 as indicated by the small-dashed lines. These components may be disposed between the set of transformers 124 and the single-ended node 326 or between the set of transformers 124 and the common differential node pair 320. Alternatively, these components may be on an opposite side of the single-ended node 326 or the common differential node pair 320 with respect to the set of transformers 124. Example implementations are depicted at FIGS. 5 and 8. In FIG. 3, the single-ended amplifier 122 is illustrated as being coupled between the “left” single-ended node 326 and the set of transformers 124 or as being coupled on the opposite side of the “right” single-ended node 326 with respect to the set of transformers 124. The single-ended amplifier 122 includes a first node 308 and a second node 310. In an example implementation that includes the “left” single-ended node 326 (but not the “right” one), the first node 308 of the single-ended amplifier 122 is coupled to the single-ended node 326, and the second node 310 of the single-ended amplifier 122 is coupled to the single-ended side 304-1 of each transformer 302 of the set of transformers 124.

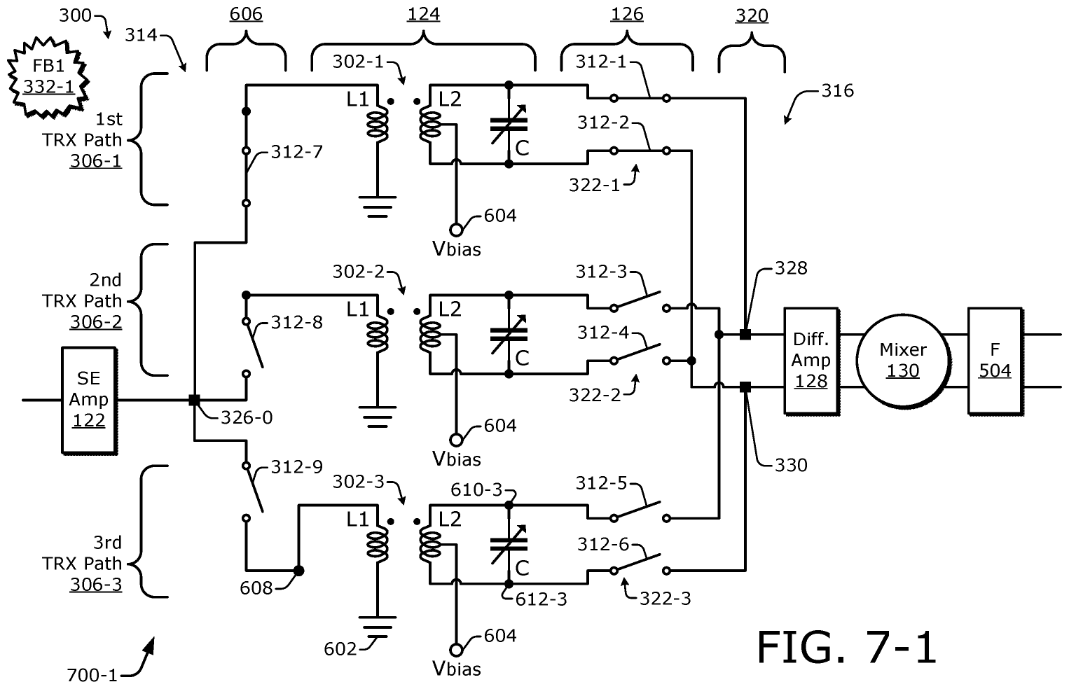

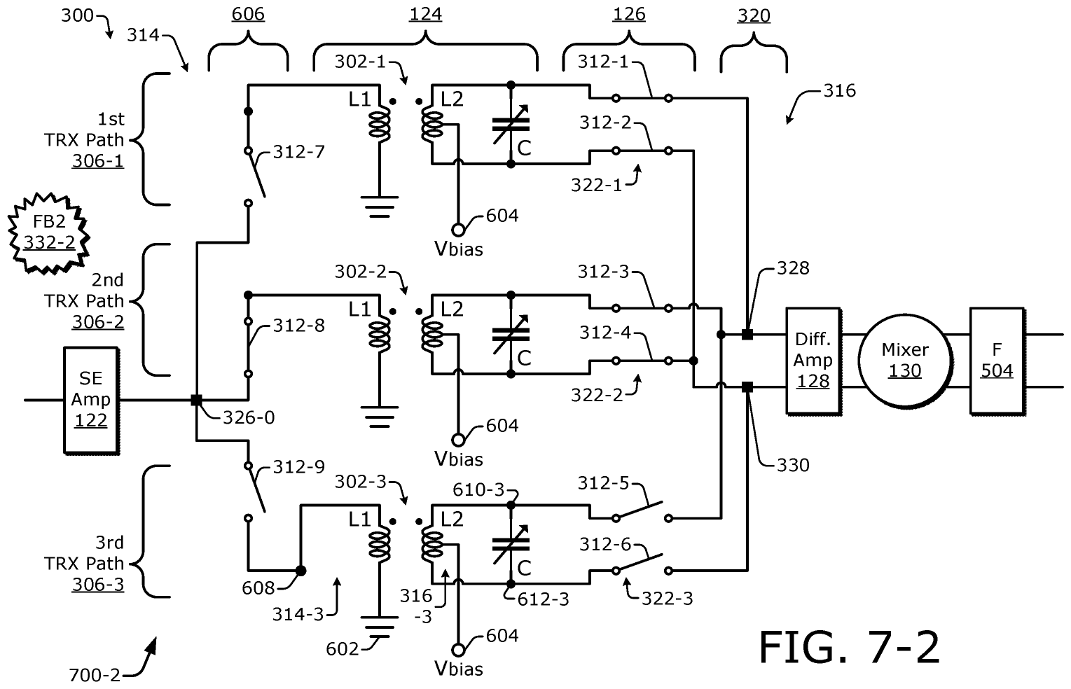

The depicted single-ended amplifier 122 can be realized as a broadband amplifier that can process signals across multiple frequency bands for multiple transceiver paths 306-1 to 306-2 (e.g., as shown in FIGS. 5 and 6) or as multiple narrowband amplifiers that respectively process signals across multiple respective frequency bands for multiple respective transceiver paths 306-1 to 306-2 (e.g., as shown in FIGS. 8 and 9). The differential transceiver component 318 is coupled to the common differential node pair 320. Thus, the differential transceiver component 318 is coupled to the plus differential node 328 and the minus differential node 330 of the common differential node pair 320. The differential transceiver component 318 can be realized as, for example, a differential amplifier, a differential mixer, a differential filter, and so forth.

Although not explicitly shown, the transceiver controller 214 is coupled to the multiple switches 312-1 to 312-4 of the differential switch circuitry 126. This enables the transceiver controller 214 to open and close the multiple switches via the switch control signal 324. The differential switch circuitry 126 includes the multiple switches 312-1 to 312-4 coupled at least between different differential sides of the multiple transformers. Thus, the differential switch circuitry 126 can provide an example switching mechanism for selectively connecting the differential side 304-2 of the first transformer 302-1 to be in parallel with the differential side 304-2 of the second transformer 302-2. Further, the transceiver controller 214 can provide an example control mechanism for operating the multiple switches to reconfigure the transformers as described herein.

For an example receiving operation, assume a received signal 210-1 (of FIG. 2) has a frequency within the second frequency band 332-2 corresponding to the second transceiver path 306-2. Thus, the received signal 210-1 is to propagate along the second transceiver path 306-2 and be processed by the second transformer 302-2 prior to being forwarded to a downstream component, such as the differential transceiver component 318. The transceiver controller 214 operates the multiple switches 312-1 to 312-4 based on the received signal 210-1 having a frequency that matches a frequency band corresponding to the second transformer 302-2 of the second transceiver path 306-2. The transceiver controller 214 establishes switch states of the multiple switches 312-1 to 312-4 to route the received signal 210-1 along the second transceiver path 306-2. The transceiver controller 214 may also activate components along the second transceiver path 306-2 and deactivate components along other transceiver paths to facilitate this signal routing, as is described further below.

Responsive to the frequency of the received signal 210-1 and based on the corresponding frequency bands of the respective receive paths, the transceiver controller 214 therefore activates the second transformer 302-2 to function as a main transformer. Further, the transceiver controller 214 engages the first transformer 302-1 to function as an auxiliary transformer. In a receiving scenario, the single-ended amplifier 122 can comprise a single-ended low-noise amplifier in which the first node 308 comprises an amplifier input and the second node 310 comprises an amplifier output. The second transformer 302-2 therefore operates as a load transformer for the single-ended amplifier 122 and receives an amplified signal from the amplifier output at the second node 310.

In this configuration in which the received wireless signal has a frequency within the second frequency band 332-2 corresponding to the second transceiver path 306-2, the second transformer 302-2 processes the amplified signal by, for instance, converting the amplified signal from single-ended signaling to differential signaling. The first transformer 302-1, on the other hand, “loans” an inductance (e.g., at least an inductance of an inductor corresponding to the differential side 304-2 thereof) to change an inductance value provided by the second transformer 302-2. In these manners, an auxiliary transformer that is not currently activated for processing a received signal can be reconfigured to provide an inductive effect in conjunction with a main transformer without relying on a separate, dedicated inductor or including another transformer to handle higher frequencies.

To implement this scenario, the transceiver controller 214 can be configured to operate the multiple switches in the following manner. For the switch couplings depicted in FIG. 3, the transceiver controller 214 can close the first through the fourth switches 312-1 to 312-4 to connect the differential side 304-2 of the first transformer 302-1 in parallel with the differential side 304-2 of the second transformer 302-2. Closing the third switch 312-3 and the fourth switch 312-4 also enables the received signal to propagate from the differential side 304-2 of the second transformer 302-2 to the common differential node pair 320 to thereby activate the second transceiver path 306-2 to process the received signal. In other implementations, one switch pair 322 may be closed instead of two switch pairs to connect in parallel the two differential sides of the two different transformers. The transceiver controller 214 can further control other switches (not shown in FIG. 3) or the active states of other components to route a signal along the appropriate transceiver path 306, as is described further herein.

FIG. 3, as well as some other figures (e.g., FIGS. 2 and 5-11), depict each transformer 302 as having a single-ended side 304-1 and a differential side 304-2. Specifically, each transformer 302 is depicted with a single-ended side 304-1 that is proximate to an antenna (e.g., on an antenna or RF side) and with a differential side 304-2 that is proximate to a mixer (e.g., on a modem or baseband side). However, one or more transformers of a given set of transformers 124 may be implemented in an alternative manner. For example, a transformer 302 may be implemented with two single-ended sides (e.g., implemented to have a single-ended interface on both first and second sides, or with both primary and secondary coils) and using single-ended signaling on both sides. Alternatively, a transformer 302 may be implemented with two differential sides (e.g., implemented to have a differential interface on both first and second sides, or with both primary and secondary coils) and using differential signaling on both sides. Thus, with these two preceding implementations, such a transformer 302 does not need to perform a conversion between balanced and unbalanced signaling. Further, a transformer 302 may be implemented with a differential side 304-2 that is proximate to an antenna (e.g., on an antenna or RF side) and with a single-ended side 304-1 that is proximate to a mixer (e.g., on a modem or baseband side). In any of these implementations, a single-ended side 304-1 can be coupled to a single-ended node 326 (e.g., to a solo or a common singled-ended node 326) of at least one single-ended node that is allocated to a set of transformers 124. Similarly, a differential side 304-2 can be coupled to a differential node pair 320 (e.g., to a solo or a common differential node pair 320) of at least one differential node pair that is allocated to a set of transformers 124.

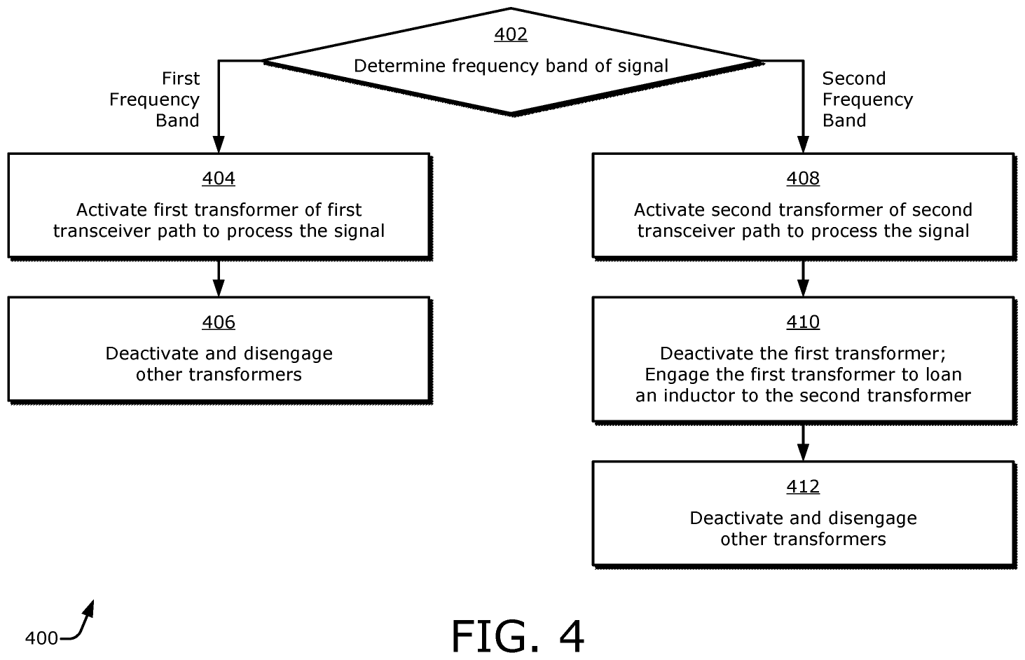

FIG. 4 is a flow diagram illustrating an example technique 400 for operating a wireless transceiver with transformer reconfigurability. The technique 400 is described in the form of a set of blocks 402-412 that specify operations that can be performed. However, operations are not necessarily limited to the order shown in FIG. 4 or described herein, for the operations may be implemented in alternative orders or in fully or partially overlapping manners. Operations represented by the illustrated blocks of the technique 400 may be performed by a wireless transceiver 120 including a transceiver path set 300 (e.g., of FIGS. 2 and 3).

At block 402, a frequency band to which a signal associated is determined. For example, the transceiver controller 214 can determine that a signal to be propagated through a wireless transceiver 120 has a frequency within a first frequency band 332-1 or a second frequency band 332-2. If the latter, the technique 400 continues with block 408 to route the wireless signal 210 through the second transceiver path 306-2. If the former (i.e., the first frequency band 332-1), the technique 400 continues with block 404 to route the wireless signal 210 through the first transceiver path 306-1.

Thus, at block 404, the first transformer of the first transceiver path is activated to process the signal. To route the signal for the first frequency band 332-1, the transceiver controller 214 can close one or more switches or activate one or more components along the first transceiver path 306-1 such that the signal propagates over the first transceiver path 306-1 and through the first transformer 302-1. In this example, the first transformer 302-1 is capable of handling the full range of the first frequency band 332-1 without using an auxiliary inductor. However, in other implementations, a separate inductor or one from another transformer can alternatively be switchably connected in parallel with the first transformer 302-1 to extend the bandwidth thereof. At block 406, other transformers in a set of transformers are deactivated and disengaged. To do so, the transceiver controller 214 can prevent the signal from propagating over other transceiver paths and can ensure that other transformers are not coupled in parallel with the first transformer 302-1.

For the second frequency band 332-2, at block 408, the second transformer of the second transceiver path is activated to process the signal. To route the signal accordingly, the transceiver controller 214 can close one or more switches or activate one or more components along the second transceiver path 306-2 such that the signal propagates over the second transceiver path 306-2 and through the second transformer 302-2. In this example, the second transformer 302-2 is augmented for higher frequencies of the second frequency band 332-2 using an auxiliary inductor that is borrowed from the first transformer 302-1.

Thus, at block 410, the first transformer is deactivated but engaged to loan at least one inductor thereof to the second transformer. The transceiver controller 214 can, for instance, open one or more switches or deactivate one or more components along the first transceiver path 306-1 to prevent the signal from propagating along the first transceiver path 306-1. Further, to engage the first transformer 302-1, the transceiver controller 214 can cause at least one switch pair 322-1 (e.g., the first switch 312-1 and the second switch 312-2) to be in a closed state so as to couple the differential side 304-2 of the first transformer 302-1 to the differential side 304-2 of the second transformer 302-2. This coupling enables an inductor of the first transformer 302-1 to be coupled in parallel with another inductor of the second transformer 302-2 to thereby engage the first transformer 302-1 to loan the inductor thereof. This parallel coupling of two inductors decreases the effective inductance of the second transformer 302-2 and increases the SRF thereof, which extends the upper frequency range of the second frequency band 332-2 that the second transformer 302-2 can successfully process.

At block 412, other transformers in a set of transformers, besides the first and second transformers, are deactivated and disengaged. For instance, the transceiver controller 214 can prevent the signal from propagating over other transceiver paths (e.g., besides the second transceiver path 306-2) and can ensure that other transformers (e.g., besides the first transformer 302-1) are not coupled in parallel with the second transformer 302-2.

FIG. 5 is a schematic diagram of a wireless transceiver portion 500 in accordance with a first example implementation that includes a set of transformers 124 in a narrowband section 508. Starting from the left of the transceiver potion 500, a transceiver switch matrix 502 (TRX Switch Matrix 502) leads to at least one antenna, such as the antenna 136 of FIG. 2. The transceiver switch matrix 502 is coupled to the single-ended amplifier 122, which is coupled to the narrowband section 508. The narrowband section 508 is coupled to the differential amplifier 128, which is coupled to the mixer 130. A filter 504 is coupled to the mixer 130, and the filter 504 leads to an analog-to-digital/digital-to-analog converter, such as the AD/DA converter 132 of FIG. 2. However, alternative implementations can include more or fewer components, different components, duplicated components (e.g., multiple filters), different orders of components, a different distribution of narrowband versus broadband components, a different distribution of single-ended versus differential components, and so forth.

As illustrated, the narrowband section 508 includes the set of transformers 124 and the differential switch circuitry 126 in between the single-ended interface 314 and the differential interface 316. As shown in, e.g., FIGS. 3 and 6, the set of transformers 124 includes multiple individual transformers, such as the transformers 302-1 to 302-3. The transformers 302-1 to 302-3 of the set of transformers 124 convert between single-ended signals and differential signals along the wireless transceiver portion 500 as indicated at the dashed line 514. Thus, a portion of the wireless transceiver to the left of the dashed line 514 is indicated to comprise a single-ended portion 510, and another portion of the wireless transceiver to the right of the dashed line 514 is indicated to comprise a differential portion 512. Further, each respective transformer 302 of the set of transformers 124 corresponds to, and is configured to process signals for, a respective frequency band as part of the narrowband section 508. In this sense, each individual transformer 302 can be implemented as a narrowband component (e.g., a narrowband transformer).

In contrast, other components that are part of a broadband section 506 can correspond to, and can be configured to process signals for, multiple frequency bands, such as low, middle, and high frequency bands. Components illustrated in the broadband section 506 include the single-ended amplifier 122, the differential amplifier 128, the mixer 130, and the filter 504. Accordingly, these other components can each be implemented as a broadband component (e.g., a broadband differential amplifier, a broadband mixer, or a broadband filter). These other components are indicated as being part of a first broadband section 506-1 (to the left of the narrowband section 508) or a second broadband section 506-2 (to the right of the narrowband section 508) of the wireless transceiver portion 500. Thus, the single-ended amplifier 122, the differential amplifier 128, the mixer 130, or the filter 504—or any combination thereof—can be implemented as a respective broadband component to further save space within the wireless transceiver. However, alternative implementations can allocate components to different broadband versus narrowband sections or different single-ended versus differential portions. Such an alternative example is described below with reference to FIG. 8.

Herein, different individual components, sets of components, transceiver paths or a part thereof, portions of transmit/receive chains, and so forth are described in terms of being tuned for a “narrowband” frequency range or a “broadband” frequency range. These narrowband versus broadband terms, however, can be relative. Thus, within a given system or context, a narrowband component is relatively narrow as compared to a broadband component that may couple to multiple such narrowband components. In other words, a narrowband frequency range for a narrowband component of a set of such narrowband components is less broad than a broadband frequency range across the set of such narrowband components. In contrast, that narrowband component may constitute a broadband component in another system of context. For a numerical example, a first implementation may entail a set of three narrowband components (e.g., a low-, a medium-, and a high-band set of narrowband components) that correspond to frequency ranges of 0.6 to 1.4 GHz, 1.5 to 2.2 GHz, and 2.2 to 2.9 GHz, respectively. A broadband component in this first implementation may therefore be tuned to handle a frequency range of 0.5 to 3.0 GHz. A second implementation may entail a set of three narrowband components (e.g., a low-, a medium-, and a high-band set of narrowband components) that correspond to frequency ranges of 10 to 13 GHz, 14 to 17.5 GHz, and 18 to 21 GHz, respectively. A broadband component in this second implementation may therefore be tuned to handle a frequency range of 10 to 21 GHz. Accordingly, “narrowband” versus “broadband” can refer to the relative widths of corresponding frequency ranges within a given implementation, context, or system.

FIG. 6-1 is a circuit diagram illustrating an example wireless transceiver portion 600-1 in accordance with the first example implementation of FIG. 5. The wireless transceiver portion 600-1 therefore includes the single-ended amplifier 122 (SE Amp 122), the set of transformers 124 with three transformers 302-1 to 302-3, the differential switch circuitry 126, the differential amplifier 128 (Diff. Amp 128), the mixer 130, and the filter 504 (F 504). Thus, the wireless transceiver portion 600-1 is similar to the wireless transceiver portions of FIGS. 3 and 5 with certain schematic components depicted with circuit components. For example, the transformers are depicted with individual inductors. Further, multiple switches 312-1 to 312-9 are separately depicted. These switches are illustrated using dashed lines to indicate an indeterminate state in FIG. 6. In contrast, each switch 312 is illustrated as being in a closed switch state or an open switch state in FIGS. 7-1 to 7-3 in accordance with a respective frequency band corresponding to a signal being processed.

In FIG. 6, the wireless transceiver portion 600-1 includes a transceiver path set 300 that extends from the single-ended interface 314 to the differential interface 316. The transceiver path set 300 includes a first transceiver path 306-1, a second transceiver path 306-2, and a third transceiver path 306-3 that each respectively includes a first transformer 302-1, a second transformer 302-2, and a third transformer 302-3. The first transceiver path 306-1 includes a first single-ended interface 314-1 and a first differential interface 316-1. The second transceiver path 306-2 includes a second single-ended interface 314-2 and a second differential interface 316-2. The third transceiver path 306-3 includes a third single-ended interface 314-3 and a third differential interface 316-3.

In addition to the plus differential node 328 and the minus differential node 330 of the common differential node pair 320 that can be located at the differential interface 316, the wireless transceiver portion 600-1 also includes a common single-ended node 326-0. The common single-ended node 326-0 can be located at the single-ended interface 314 of the transceiver path set 300. The wireless transceiver portion 600-1 further includes single-ended switch circuitry 606. In some implementations, the single-ended switch circuitry 606 is coupled between each transceiver path 306 of the transceiver path set 300 and the common single-ended node 326-0 as shown. The single-ended switch circuitry 606 includes three switches: a seventh switch 312-7, an eighth switch 312-8, and a ninth switch 312-9. The seventh switch 312-7 is coupled between the common single-ended node 326-0 and the first transformer 302-1. The eighth switch 312-8 is coupled between the common single-ended node 326-0 and the second transformer 302-2. The ninth switch 312-9 is coupled between the common single-ended node 326-0 and the third transformer 302-3. Thus, the transceiver path set 300 as depicted in FIG. 6-1 comprises a single-input, single-output (SISO) section of a wireless transceiver.

As shown in FIG. 6-1 for each transformer 302, each of the single-ended side 304-1 and the differential side 304-2 (of FIG. 3) can be implemented with at least one inductor (e.g., an inductive coil). Here, each single-ended side 304-1 is implemented as a first inductor (a single-ended or first inductor L1), and each differential side 304-2 is implemented as a second inductor (a differential or second inductor L2). With reference to the third transformer 302-3 by way of example, the first inductor L1 is coupled between a node 608 and ground 602. This forms at least a portion of a third single-ended interface 314-3. For a third differential interface 316-3, the second inductor L2 is coupled between two differential nodes—a third plus node 610-3 and a third minus node 612-3. The third plus node 610-3 and the third minus node 612-3 can be selectively caused to electrically correspond to the plus differential node 328 and the minus differential node 330, respectively, using a third switch pair 322-3. The third switch pair 322-3 includes a fifth switch 312-5 and a sixth switch 312-6 for the third transformer 302-3. The first transceiver path 306-1 and the second transceiver path 306-2 include analogous versions of a plus node 610 and a minus node 612. The analogous nodes are located at opposite ends of the respective second inductors L2 for the first and second transformers 302-1 and 302-2. These nodes include a first plus node 610-1 and a first minus node 612-1 and also include a second plus node 610-2 and a second minus node 612-2.

A capacitor C, which can be adjustable and implemented as a capacitor bank, is also coupled between the plus and minus nodes 610 and 612 in parallel with the second inductor L2. The second inductor L2 and the capacitor C form a capacitive-inductive tank (LC tank) that can tune a signal that transits the transformer. Accordingly, the capacitive and inductive values thereof can be selected (during design or during operation if programmable) based on a corresponding frequency band for signals to be processed by the associated transformer for the corresponding transceiver path 306. Further, the tuning can be programmable by utilizing an adjustable capacitor C or a segregated capacitor bank 212, which is described below with reference to FIG. 11. The second inductor L2 can be biased using a voltage bias 604 (Vbias 604), which can be coupled to a tap—such as a center tap—of the second inductor L2. Generally, each transformer 302 has a first inductor L1 that is coupled between a respective node and the ground 602. Each transformer 302 also has a second inductor L2 that is coupled between two differential plus and minus nodes 610 and 612 and in parallel with a respective adjustable capacitor C. Other respective switch pairs (e.g., the first switch pair 322-1 and the second switch pair 322-2) can selectively couple a differential side of each respective transformer 302 to the common differential node pair 320.

In some implementations, each respective transformer 302 is designed, fabricated, or tuned (e.g., via the adjustable capacitor C) to correspond to the respective frequency band 332 of the respective transceiver path 306. Thus, the first transformer 302-1 corresponds to the first frequency band 332-1 (FB1) and forms a part of the first transceiver path 306-1. The second transformer 302-2 corresponds to the second frequency band 332-2 (FB2) and forms a part of the second transceiver path 306-2. The third transformer 302-3 corresponds to a third frequency band 332-3 (FB3) and forms a part of the third transceiver path 306-3. A transceiver controller 214 (e.g., of FIGS. 2 and 3) can control the switches of the single-ended switch circuitry 606 and the differential switch circuitry 126 to reconfigure the multiple transformers 302-1 to 302-3 such that at least one transformer 302 can be employed to process a signal in one frequency band and reused on behalf of another transformer 302 to extend another frequency band corresponding to the other transformer 302. This is described further with reference to FIGS. 7-1 to 7-3.

In some implementations, an inductor for one transformer can be shared with another transformer by coupling the inductors in series relative to a downstream component, such as the differential amplifier 128. For example, the second transformer 302-2 can share the second inductor L2 thereof with the third transformer 302-3. To do so, at least one additional switch and wire connection is included in the circuit as depicted in FIG. 6. For instance, a path can be established from the minus differential node 330 to the plus differential node 328 as follows. The fourth and fifth switches 312-4 and 312-5 are both placed in an open switch state, and the third and sixth switches 312-3 and 312-6 are both placed in a closed switch state. From the minus differential node 330, the path extends over the closed sixth switch 312-6, to the third minus node 612-3, through the second inductor L2 of the third transformer 302-3 (also in parallel with the capacitor C thereof), and to the third plus node 610-3. From the third plus node 610-3, a switch (not shown) is closed that extends the path over that switch, to the second minus node 612-2, through the second inductor L2 of the second transformer 302-2 (also in parallel with the capacitor C thereof), to the second plus node 610-2, over the closed third switch 312-3, and to the plus differential node 328.

Although examples of the set of transformers 124 are depicted in FIGS. 3 and 6-1 as having two and three individual transformers, respectively, a set of transformers 124 may have four or more individual transformers. In some implementations, each individual transformer 302 and associated transceiver path 306 corresponds to a respective frequency band 332. Thus, a wireless transceiver with a set of transformers 124 that includes three transformers 302-1, 302-2, and 302-3 (or another component set that includes three narrowband components in a narrowband section 508) can process wireless signals across three different frequency bands using three respective signal propagation paths.

FIG. 6-2 is a circuit diagram illustrating an example wireless transceiver portion 600-2 in accordance with the first example implementation of FIG. 5. The wireless transceiver portion 600-2 therefore includes the single-ended amplifier 122, the set of transformers 124 with three transformers 302-1 to 302-3, the differential switch circuitry 126, the differential amplifier 128 (Diff. Amp 128), the mixer 130, and the filter 504 (F 504). Thus, the wireless transceiver portion 600-2 is similar to the wireless transceiver portion 600-1 of FIG. 6-1. However, the wireless transceiver portion 600-2 includes a signal bypass path 614 that is switchably coupled to a node 616 (e.g., on a same side with the first node 308 of the single-ended amplifier 122) and a node 618 (e.g., on a same side as the second node 310). The signal bypass path 614 is schematically depicted in FIG. 6-2 as a curved line that can be selectively enabled to cause a signal to detour around the single-ended amplifier 122.

In example implementations, the single-ended amplifier 122 can be selectively deactivated (e.g., turned off) as indicated by the “X” mark and unused for signal processing. Further, the input node 308 and the output node 310 of the single-ended amplifier 122 can be shorted. To enable the singled-ended switch circuitry 606, the set of transformers 124, etc. to process a received signal with the single-ended amplifier 122 being deactivated, the signal bypass path 614 is engaged, such as by closing one or more switches (not explicitly shown) that switchably couple the signal bypass path 614 to the signal propagation path on both sides of the singled-ended amplifier 122 at the node 616 and the node 618. While engaged, a received signal propagates along the signal bypass path 614 to thereby travel around the single-ended amplifier 122. If the single-ended amplifier 122 is to be used again to amplify a received signal, the single-ended amplifier 122 is activated, the first node 308 and the second node 310 of the single-ended amplifier 122 are un-shorted, and the signal bypass path 614 is disengaged by decoupling it from at least one of the first node 308 or the second node 310 via the node 616 or the node 618, respectively. The signal bypass path 614 may be switchably coupled to the signal propagation path and/or around the single-ended amplifier 122 in alternative manners. Thus, implementations that are described herein that are indicated to pertain to the wireless transceiver portion 600-1 of FIG. 6-1 (e.g., general descriptions and those implementations of FIGS. 5, 6-1, 7-1, 7-2, 7-3, 11, and 12), are also applicable to the wireless transceiver portion 600-2 of FIG. 6-2.

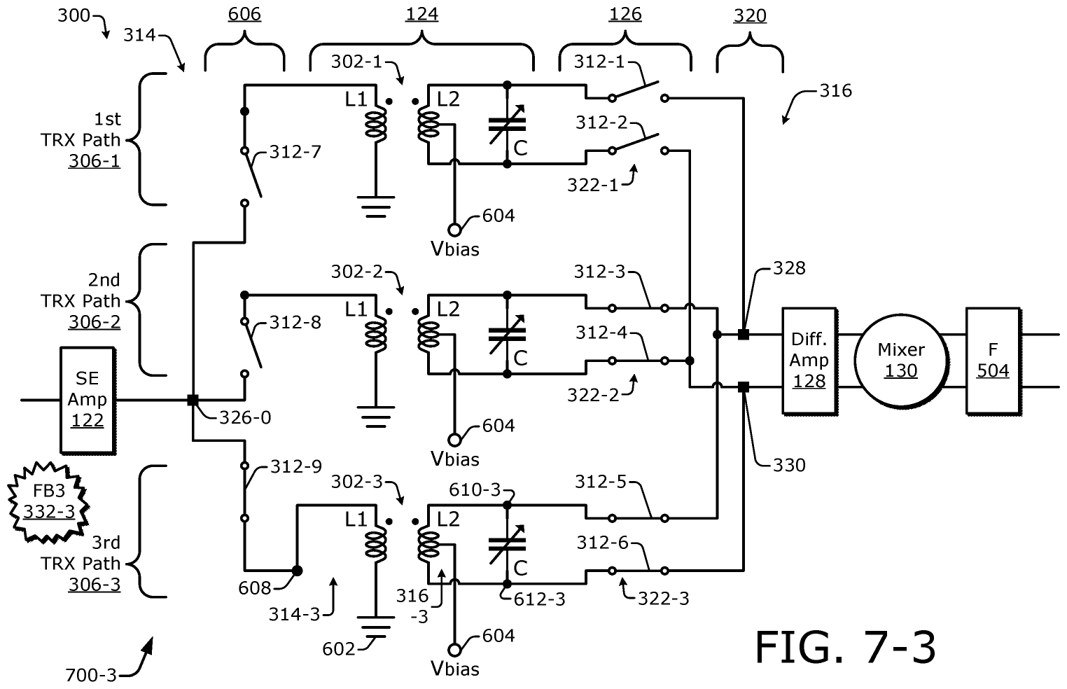

FIGS. 7-1, 7-2, and 7-3 are circuit diagrams of the wireless transceiver portion 600-1 of FIG. 6-1 with certain switches in associated example switch states for a first, second, and third frequency band, respectively. FIG. 7-1 is a circuit diagram 700-1 of the wireless transceiver portion 600-1 in an example first configuration corresponding to a first frequency band 332-1 (FB1) (e.g., a relatively low frequency band) with certain switches in associated switch states. A wireless signal (e.g., a first signal) being processed is therefore to be routed along the first transceiver path 306-1. Accordingly, the transceiver controller 214 (e.g., of FIG. 3) activates the first transformer 302-1 and the corresponding transceiver path 306-1 to process the signal and couple the signal to a downstream component via the common differential node pair 320 (e.g., for an example receive chain implementation). In this example, for the first frequency band 332-1, no additional inductance is employed to extend a frequency range of the first transformer 302-1. Instead, the baseline components can be designed to achieve an acceptable frequency range for the first frequency band 332-1. Thus, the transceiver controller 214 deactivates and disengages the second and third transformers 302-2 and 302-3 and the corresponding transceiver paths 306-2 and 306-3, respectively, for this first configuration.

To achieve these activation and deactivations, the transceiver controller 214 generates at least one switch control signal 324 to close the seventh switch 312-7 and the first and second switches 312-1 and 312-2. The at least one switch control signal 324 further opens the other six switches, namely the third through the sixth switches 312-3 to 312-6, the eighth switch 312-8, and the ninth switch 312-9. Consequently, a propagating signal can flow across the single-ended amplifier 122 and through the common single-ended node 326-0, be routed to the first inductor L1 of the first transformer 302-1 via the seventh switch 312-7 being in a closed state, transit the first transformer 302-1, and be routed to the plus differential node 328 and the minus differential node 330 over the first and second switches 312-1 and 312-2.

FIG. 7-2 is a circuit diagram 700-2 of the wireless transceiver portion 600-1 of FIG. 6-1 in an example second configuration corresponding to a second frequency band 332-2 (FB2) (e.g., a relatively middle frequency band) with certain switches in associated switch states. A wireless signal (e.g., a second signal) is therefore to be routed along the second transceiver path 306-2. Accordingly, the transceiver controller 214 (e.g., of FIG. 3) activates the second transformer 302-2 and the corresponding transceiver path 306-2 to process the signal and couple the signal to a downstream component via the common differential node pair 320 (e.g., for an example receive chain implementation). In this example, for the second frequency band 332-2, additional inductance is employed by engaging the first transformer 302-1 to reuse the inductance thereof (e.g., to reuse the second inductor L2 or the second inductor L2 in conjunction with the first inductor L1 of the first transformer 302-1). Loaning this inductance extends a frequency range of the second frequency band 332-2 that can be handled by the second transformer 302-2. The transceiver controller 214 also deactivates and disengages the third transformer 302-3 and the corresponding transceiver path 306-3 for this second configuration.

To achieve the activation, engagement, and deactivation of these three transformers, the transceiver controller 214 generates at least one switch control signal 324 to control switch states of the nine switches. Specifically, the transceiver controller 214 closes the first and second switches 312-1 and 312-2 to couple the second inductor L2 of the first transformer 302-1 to the differential side of the second transformer 302-2 and opens the seventh switch 312-7. These switch states deactivate the first transformer 302-1 from processing the signal but engage the first transformer 302-1 to loan an inductance thereof to the second transformer 302-2 by coupling the two second inductors L2 in parallel with each other. The at least one switch control signal 324 also closes the eighth switch 312-8 as well as the third and fourth switches 312-3 and 312-4. This activates the second transformer 302-2 of the second transceiver path 306-2 for processing and forwarding of the signal to another component (e.g., the differential amplifier 128).

The transceiver controller 214 further opens the remaining three switches, namely both the fifth and sixth switches 312-5 and 312-6 and the ninth switch 312-9. Opening these three switches deactivates and disengages the third transformer 302-3 of the third transceiver path 306-3. Consequently, a propagating signal can flow across the single-ended amplifier 122 and through the common single-ended node 326-0 and be routed to the first inductor L1 of the second transformer 302-2 via the eighth switch 312-8 being in a closed state. The propagating signal further transits the second transformer 302-2 and is routed to the common differential node pair 320 (e.g., the plus differential node 328 and the minus differential node 330) over the third and fourth switches 312-3 and 312-4, which are closed. Here, the signal transits the second transformer 302-2, including a differential side thereof that has an inductive value based both on the second inductor L2 of the second transformer 302-2 and on the second inductor L2 of the first transformer 302-1.

FIG. 7-3 is a circuit diagram 700-3 of the wireless transceiver portion 600-1 of FIG. 6-1 in an example third configuration corresponding to the third frequency band 332-3 (FB3) (e.g., a relatively high frequency band) with certain switches in associated switch states. A wireless signal (e.g., a third signal) is therefore to be routed along the third transceiver path 306-3. Accordingly, the transceiver controller 214 (e.g., of FIG. 3) activates the third transformer 302-3 and the corresponding transceiver path 306-3 to process the signal and couple the signal to a downstream component (e.g., the differential amplifier 128 for a receive operation and the single-ended amplifier 122 for a transmit operation). In this example, for the third frequency band 332-3, additional inductance is employed by engaging the second transformer 302-2 to reuse the inductance thereof (e.g., to reuse the second inductor L2 or the second inductor L2 in conjunction with the first inductor L1 of the second transformer 302-2). Loaning this inductance extends a frequency range of the third frequency band 332-3 that can be handled by the third transformer 302-3. The transceiver controller 214 also deactivates and disengages the first transformer 302-1 and the corresponding transceiver path 306-1 for the third configuration.

To achieve the activation, engagement, and deactivation of these three transformers, the transceiver controller 214 generates at least one switch control signal 324 to control switch states of the nine switches. Specifically, the transceiver controller 214 closes the third and fourth switches 312-3 and 312-4 to couple the second inductor L2 of the second transformer 302-2 to the differential side of the third transformer 302-3 and opens the eighth switch 312-8. This engages the second transformer 302-2 to loan an inductance thereof to the third transformer 302-3 by coupling the two second inductors L2 in parallel with each other but deactivates the second transformer 302-2 from processing the propagating signal. The at least one switch control signal 324 also closes the fifth and sixth switches 312-5 and 312-6 as well as the ninth switch 312-9. This activates the third transformer 302-3 of the third transceiver path 306-3 for processing and forwarding of the signal to another component (e.g., to the differential amplifier 128 for an example receive chain implementation).

The transceiver controller 214 further opens the remaining three switches, namely both the first and second switches 312-1 and 312-2 and the seventh switch 312-7. Opening these three switches deactivates and disengages the first transformer 302-1 of the first transceiver path 306-1 from processing the propagating signal and from affecting the inductance of the third transformer 302-3, respectively. Consequently, a propagating signal can flow across the single-ended amplifier 122 and through the common single-ended node 326-0 and be routed to the first inductor L1 of the third transformer 302-3 via the ninth switch 312-9 being in a closed state. The propagating signal further transits the third transformer 302-3 and is routed to the common differential node pair 320 (e.g., the plus differential node 328 and the minus differential node 330) over the fifth and sixth switches 312-5 and 312-6. Here, the signal transits the third transformer 302-2, including a differential side thereof that has an inductive value based both on the second inductor L2 of the third transformer 302-3 and on the second inductor L2 of the second transformer 302-2.

FIG. 8 is a schematic diagram of a wireless transceiver portion 800 in accordance with a second example implementation that includes a set of singled-ended amplifiers 802 (Set of SE Amplifiers 802), the set of transformers 124, and a set of mixers 804 in a narrowband section 508. The wireless transceiver portion 800 also includes a broadband section 506 that includes the differential amplifier 128 and the filter 504. The narrowband section 508 extends between the single-ended interface 314 and the differential interface 316. Starting from the left of FIG. 8 in the narrowband section 508, the set of singled-ended amplifiers 802 leads to at least one antenna, such as the antenna 136 of FIG. 2.

The set of singled-ended amplifiers 802 is also coupled to the set of transformers 124, and the set of transformers 124 is coupled to the set of mixers 804. The differential switch circuitry 126 is coupled to the set of transformers 124 between the set of transformers 124 and the set of mixers 804. As shown in, e.g., FIGS. 3 and 9, the set of transformers 124 includes multiple individual transformers, such as the transformers 302-1 to 302-3. Similarly, the set of singled-ended amplifiers 802 includes multiple individual single-ended amplifiers, and the set of mixers 804 includes multiple individual mixers (e.g., as shown in FIG. 9). Further, each individual narrowband component of each set of components in the narrowband section 508 is designed to handle signals within a respective frequency band such that the overall component set can handle a broadband frequency range. Examples of these three sets of components are illustrated in greater detail in FIG. 9.

The set of mixers 804 of the narrowband section 508 is coupled to the broadband section 506. Thus, the set of mixers 804 is coupled to the differential amplifier 128, which is coupled to the filter 504. The filter 504 leads to an analog-to-digital/digital-to-analog converter, such as the AD/DA converter 132 of FIG. 2. In contrast with the components of the narrowband section 508, the components that are part of the broadband section 506 can correspond to, and can be configured to process signals for, multiple frequency bands, such as low, middle, and high frequency bands to cover a broadband frequency range. Accordingly, these other components can each be implemented as a broadband component (e.g., a broadband differential amplifier or a broadband filter). Thus, the differential amplifier 128 or the filter 504—or any combination thereof—can be implemented as a respective broadband component to further save space within the wireless transceiver.

The transformers 302-1 to 302-3 of the set of transformers 124 convert between single-ended signals and differential signals along the wireless transceiver portion 800 as indicated at the dashed line 514. Thus, a portion of the wireless transceiver to the left of the dashed line 514 is indicated to comprise a single-ended portion 510 that propagates single-ended signals, and another portion of the wireless transceiver to the right of the dashed line 514 is indicated to comprise a differential portion 512 that propagates differential signals. Although a particular arrangement of components is depicted in FIG. 8 and described above, alternative implementations of the wireless transceiver portion 800 can include more or fewer components, different components, duplicated components (e.g., multiple broadband filters coupled together in series), different orders of components, a different distribution of narrowband versus broadband components, a different distribution of single-ended versus differential components, and so forth.

FIG. 9 is a circuit diagram illustrating an example wireless transceiver portion 900 in accordance with the second example implementation of FIG. 8. The wireless transceiver portion 900 therefore includes the set of singled-ended amplifiers 802, the set of transformers 124, the differential switch circuitry 126, the set of mixers 804, the common differential node pair 320, the differential amplifier 128, and the filter 504. Thus, the wireless transceiver portion 900 is similar to the wireless transceiver portions of FIGS. 3 and 8 with certain schematic components represented in an exploded view or depicted with circuit components. For example, multiple individual mixers are shown for the set of mixers 804, and the individual transformers are depicted with primary and secondary inductors. Further, multiple switches 312-1 to 312-4 are separately depicted for the differential switch circuitry 126. These switches are illustrated using dashed lines to indicate an indeterminate state in FIG. 9. In contrast, each switch 312 is illustrated as being in a closed switch state or an open switch state in FIGS. 10-1 to 10-3 in accordance with a frequency band corresponding to a signal being processed.

As shown in FIG. 9, the wireless transceiver portion 900 includes a transceiver path set 300 that extends from the single-ended interface 314 to the differential interface 316. In example implementations, each component set includes multiple components respectively distributed across the multiple transceiver paths 306-1 to 306-2 of the transceiver path set 300. The set of singled-ended amplifiers 802 includes multiple single-ended amplifiers: a first single-ended amplifier 122-1, a second single-ended amplifier 122-2, and a third single-ended amplifier 122-3. The set of transformers 124 includes multiple transformers: the first transformer 302-1, the second transformer 302-2, and the third transformer 302-3. The set of mixers 804 includes multiple mixers: a first mixer 130-1, a second mixer 130-2, and a third mixer 130-3.

The transceiver path set 300 includes a first transceiver path 306-1, a second transceiver path 306-2, and a third transceiver path 306-3 coupled together substantially in parallel between respective ones of multiple single-ended nodes 326-1 to 326-3 and the common differential node pair 320, which includes the plus differential node 328 and the minus differential node 330. The wireless transceiver portion 900 therefore also includes multiple single-ended nodes: a first single-ended node 326-1, a second single-ended node 326-2, and a third single-ended node 326-3. Each of the first, second, and third transceiver paths 306-1, 306-2, and 306-3 is respectively associated with the first, second, and third single-ended nodes 326-1, 326-2, and 326-3.

These multiple single-ended nodes 326-1 to 326-3 can be located at the single-ended interface 314 of the transceiver path set 300 and respectively at the multiple single-ended interfaces 314-1 to 314-3 of the multiple transceiver paths 306-1 to 306-3. Each respective single-ended node 326 can be coupled to a respective antenna 136, e.g., via a respective quadrature amplifier (e.g., a quadrature low-noise amplifier 206 or a quadrature power amplifier 208 of FIG. 2). Specifically, the first transceiver path 306-1 includes a first single-ended interface 314-1 and a first differential interface 316-1. The second transceiver path 306-2 includes a second single-ended interface 314-2 and a second differential interface 316-2. The third transceiver path 306-3 includes a third single-ended interface 314-3 and a third differential interface 316-3. Thus, the transceiver path set 300 as depicted in FIG. 9 comprises a multiple-input, single-output (MISO) section of a wireless transceiver.

Each respective transceiver path 306 includes a respective component of the set of singled-ended amplifiers 802, the set of transformers 124, and the set of mixers 804. Thus, the first transceiver path 306-1 includes the first single-ended amplifier 122-1, the first transformer 302-1, and the first mixer 130-1 coupled together in series between the first single-ended node 326-1 and the common differential node pair 320. The second transceiver path 306-2 includes the second single-ended amplifier 122-2, the second transformer 302-2, and the second mixer 130-2 coupled together in series between the second single-ended node 326-2 and the common differential node pair 320. The third transceiver path 306-3 includes the third single-ended amplifier 122-3, the third transformer 302-3, and the third mixer 130-3 coupled together in series between the third single-ended node 326-3 and the common differential node pair 320.

As described above with reference to FIG. 6, each respective transformer 302 of the set of transformers 124 corresponds to, and is configured to process signals for, a respective frequency band as part of the narrowband section 508. In this sense, each individual transformer 302 can be implemented as a narrowband component (e.g., a narrowband transformer). Similarly, each respective single-ended amplifier 122 of the set of singled-ended amplifiers 802 and each respective mixer 130 of the set of mixers 804 corresponds to, and is configured to process signals for, a respective frequency band as part of the narrowband section 508. Thus, each single-ended amplifier 122 can be implemented as a narrowband single-ended amplifier, and each mixer 130 can be implemented as a narrowband mixer for the respective frequency band 332 corresponding to the associated transceiver path 306.

In the example second implementation depicted in FIG. 9, activation of a transformer 302 and an associated transceiver path 306 can be performed independently from engaging a transformer 302 to loan an inductor to another transformer 302. To activate a transceiver path 306, the associated active or powered components of the path (e.g., the single-ended amplifier 122 and the mixer 130) can be activated to permit a signal to propagate through the components. Conversely, to deactivate a transceiver path 306, at least one component associated with the path (e.g., the single-ended amplifier 122 or the mixer 130) is deactivated to block a signal from propagating through the component. Alternatively, a separate switch can be placed along a path of signal travel to permit or block signal propagation through a transceiver path 306.

The differential switch circuitry 126 is used to engage a given transformer 302 to share an inductor thereof with another transformer 302. The first switch pair 322-1, which includes the first switch 312-1 and the second switch 312-2, is coupled between the differential side 304-2 (of FIG. 3) of the first transformer 302-1 and the differential side 304-2 of the second transformer 302-2. Hence, closing the first and the second switches 312-1 and 312-2 causes the second inductor L2 of the first transformer 302-1 to be coupled in parallel with the second inductor L2 of the second transformer 302-2. Analogously, the second switch pair 322-2, which includes the third switch 312-3 and the fourth second switch 312-4, is coupled between the differential side 304-2 (of FIG. 3) of the second transformer 302-2 and the differential side 304-2 of the third transformer 302-3. Hence, closing the third and the fourth switches 312-3 and 312-4 causes the second inductor L2 of the second transformer 302-2 to be coupled in parallel with the second inductor L2 of the third transformer 302-3.

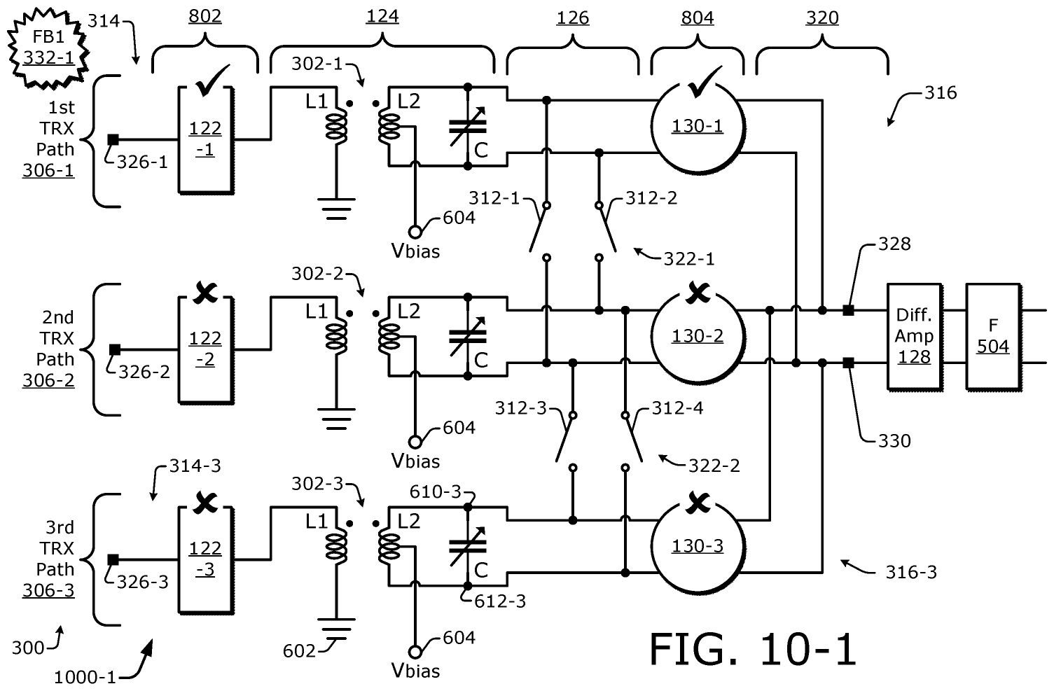

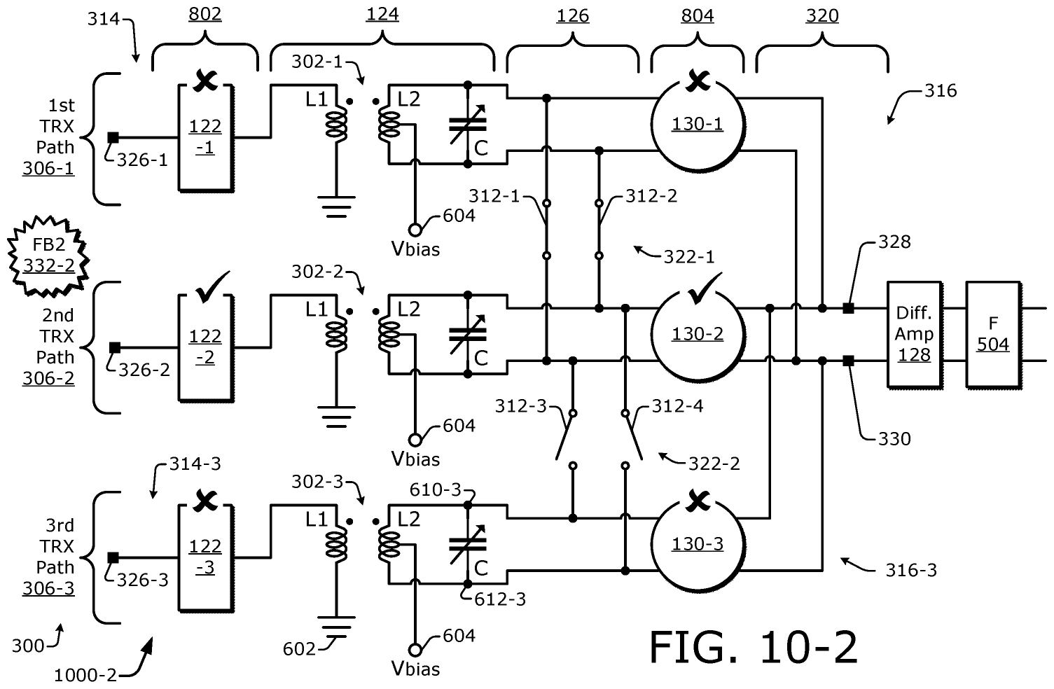

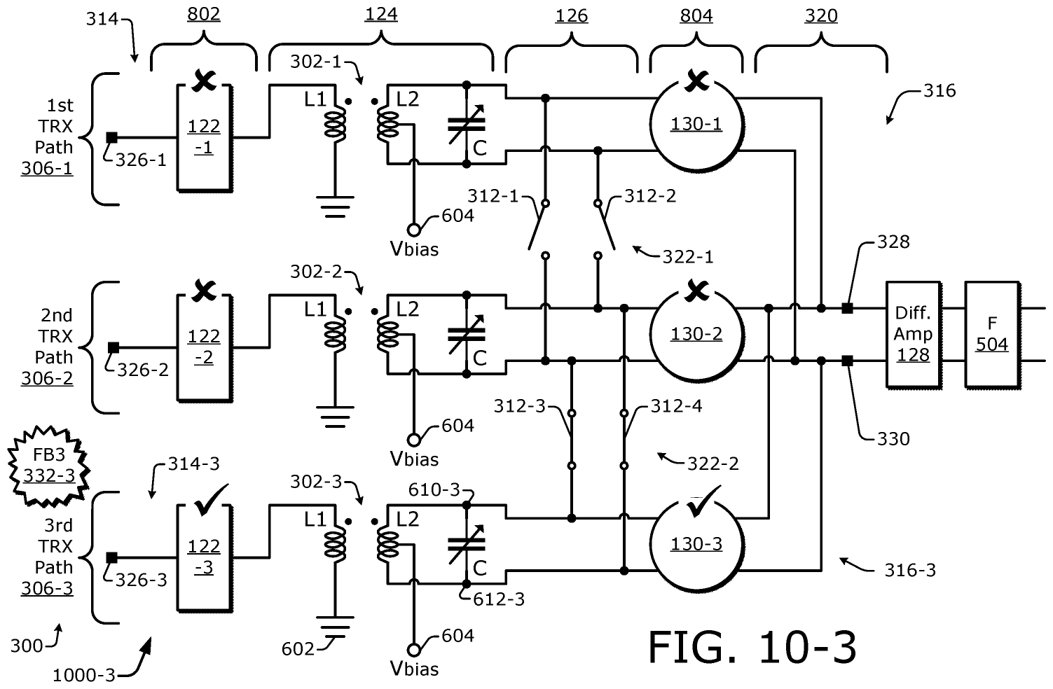

FIGS. 10-1, 10-2, and 10-3 are circuit diagrams 1000-1, 1000-2, and 1000-3 of the wireless transceiver portion 900 of FIG. 9 with certain switches in associated example switch states for first, second, and third frequency bands, respectively. In FIG. 10-1, a wireless signal (e.g., a first signal) to be processed has a frequency within the first frequency band 332-1, so the transceiver controller 214 (e.g., of FIG. 3) generates at least one switch control signal 324 to cause the signal to be routed along the first transceiver path 306-1. The switch control signal 324 also establishes appropriate switch states for the differential switch circuitry 126 based on the first frequency band 332-1. Here, the transceiver controller 214 activates the first single-ended amplifier 122-1 and the first mixer 130-1 (as indicated by the “check” mark) to activate the first transceiver path 306-1. The transceiver controller 214 deactivates at least one of the second single-ended amplifier 122-2 (as indicated by the “x” mark) or the second mixer 130-2 to deactivate the second transceiver path 306-2 and deactivates at least one of the third single-ended amplifier 122-3 or the third mixer 130-3 to deactivate the third transceiver path 306-3. In this example, no inductance is shared for the first frequency band 332-1, so no switches of the differential switch circuitry 126 are closed.

In FIG. 10-2, a wireless signal (e.g., a second signal) to be processed has a frequency within the second frequency band 332-2, so the transceiver controller 214 (e.g., of FIG. 3) generates at least one switch control signal 324 to cause the signal to be routed along the second transceiver path 306-2. The switch control signal 324 also establishes appropriate switch states for the differential switch circuitry 126 based on the second frequency band 332-2. Thus, the transceiver controller 214 activates the second single-ended amplifier 122-2 and the second mixer 130-2 to activate the second transceiver path 306-2. The transceiver controller 214 deactivates at least one of the first single-ended amplifier 122-1 or the first mixer 130-1 to deactivate the first transceiver path 306-1 and deactivates at least one of the third single-ended amplifier 122-3 or the third mixer 130-3 to deactivate the third transceiver path 306-3. In this example, the inductance of the first transformer 302-1 is to be shared with the second transformer 302-2 to extend the frequency range of the second frequency band 332-2 for the second transformer 302-2. Accordingly, the transceiver controller 214 closes the first switch pair 322-1 (e.g., the first switch 312-1 and second switch 312-2) so that the second inductor L2 of the differential side of the first transformer 302-1 is coupled in parallel with the second inductor L2 of the differential side of the second transformer 302-2.

In FIG. 10-3, a wireless signal (e.g., a third signal) to be processed has a frequency within the third frequency band 332-3, so the transceiver controller 214 (e.g., of FIG. 3) generates at least one switch control signal 324 to cause the signal to be routed along the third transceiver path 306-3. The switch control signal 324 also establishes appropriate switch states for the differential switch circuitry 126 based on the third frequency band 332-3. Thus, the transceiver controller 214 activates the third single-ended amplifier 122-3 and the third mixer 130-3 to activate the third transceiver path 306-3. The transceiver controller 214 deactivates at least one of the first single-ended amplifier 122-1 or the first mixer 130-1 to deactivate the first transceiver path 306-1 and deactivates at least one of the second single-ended amplifier 122-2 or the second mixer 130-2 to deactivate the second transceiver path 306-2. In this example, the inductance of the second transformer 302-2 is to be shared with the third transformer 302-3 to extend the frequency range of the third frequency band 332-3 with regard to the third transformer 302-3. Accordingly, the transceiver controller 214 closes the second switch pair 322-2 (e.g., the third switch 312-3 and fourth switch 312-4) so that the second inductor L2 of the differential side of the second transformer 302-2 is coupled in parallel with the second inductor L2 of the differential side of the third transformer 302-3.

In certain figures (e.g., FIGS. 3, 6, 7-1 to 7-3, 9, and 10-1 to 10-3), each transformer path 306 of a transceiver path set 300 is depicted as being switchably coupled to a same common differential node pair 320—e.g., the plus differential node 328 and the minus differential node 330. In other words, the illustrated transformer paths do not each have their own complete and exclusive receive chains. This corresponds to the multiple transformers 302-1 to 302-3 of the set of transformers 124 sharing at least one single downstream component (e.g., a differential transceiver component 318), such as a broadband differential amplifier 128 or a broadband filter 504, that is part of a joint receive chain. However, each transformer 302 of the set of transformers 124 may alternatively be coupled to respective separate downstream components, such as individual narrowband differential amplifiers and individual narrowband mixers, to provide each transformer path its own separate receive chain. In other words, each of the multiple transformers 302-1 to 302-3 may be coupled to an individual respective portion of a downstream receive chain that extends from a respective transformer 302 along one or more components of a respective downstream receive chain (e.g., toward or to a baseband modem).

In such cases, two transformers may be simultaneously accepting a signal from a common broadband single-ended low-noise amplifier 122 (e.g., of FIGS. 5, 6, and 7-1 to 7-3) or from a respective individual narrowband single-ended amplifier 122 (e.g., of FIGS. 8, 9, and 10-1 to 10-3) (e.g., two transformers may be activated for signal processing) while another transformer shares an inductor to extend a frequency range (e.g., while another transformer is engaged to support one or both activated transformers). For example, to engage the first transformer 302-1 for frequency bandwidth extension and to activate the second and third transformers 302-2 and 302-3 for signal processing, particular switches are closed/opened and particular components are activated or deactivated as follows. First, the second and third single-ended amplifiers 122-2 and 122-3 and the second and third mixers 130-2 and 130-3 are activated. Second, the first single-ended amplifier 122-1 and the first mixer 130-1 are deactivated. Also, the first and second switches 312-1 and 312-2 are closed to extend a second frequency band 332-2. Alternatively, another pair of switches (not shown) that can couple the second inductor L2 of the first transformer 302-1 to the second inductor L2 of the third transformer 302-3 are closed to extend a third frequency band 332-3.

FIG. 11 is a circuit diagram 1100 that depicts an example segregated capacitor bank 212 that can be coupled to a transformer 302. For example, the segregated capacitor bank 212 can be substituted for the adjustable tuning capacitor C of the first transformer 302-1 and the first switch pair 322-1 of the differential switch circuitry 126. As indicated in the lower half of FIG. 11, the segregated capacitor bank 212 can be incorporated into each transceiver path 306 at the first plus node 610-1, the first minus node 612-1, the plus differential node 328, and the minus differential node 330. Thus, the illustrated segregated capacitor bank 212 can be incorporated into the first example implementation of FIGS. 5 to 7-3 as shown.

As illustrated in the top portion of the circuit diagram 1100, the segregated capacitor bank 212 extends from the first plus node 610-1 (1st_P_Node 610-1) and the first minus node 612-1 (1st_M_Node 612-1) to the plus differential node 328 and the minus differential node 330 of the common differential node pair 320. The plus signaling pathways are shown with thicker lines for visual clarity. A main capacitor Cm and a main-enable switch pair 1102 are coupled along a “lower half” (as depicted) part of the segregated capacitor bank 212 between the first plus and minus nodes 610-1 and 612-1 and the plus and minus differential nodes 328 and 330. The main-enable switch pair 1102 can replace the first switch pair 322-1. Thus, the switches of the main-enable switch pair 1102 are closed to activate the first transceiver path 306-1 and opened to deactivate the first transceiver path 306-1.

A programmable capacitor C can be adjusted based on a frequency of a signal being processed by a transceiver path 306. Generally, a frequency coverage of a single transformer can be broadened by increasing an adjustable capacitance range of an associated capacitor. A large capacitance value is used to lower a frequency of a lower end of the frequency coverage of the transformer. Further, to increase an upper end of the frequency coverage, the capacitance resolution can be made to be finer. However, merely increasing the potential capacitance value adds appreciable parasitic capacitance that can limit the upper end of the frequency coverage of the transformer. These factors therefore work at cross purposes: lowering the lower end of the frequency coverage of a transformer jeopardizes an ability to increase the upper end of the frequency coverage.

To address both of these factors, the adjustable capacitor is segregated into two or more banks. In the illustrated example, the segregated capacitor bank 212 includes a main capacitor Cm and an auxiliary capacitor Ca. However, the auxiliary capacitor Ca can be substantially isolated from the associated transformer using double switch pairs that surround the auxiliary capacitor Ca on two sides. These two switch pairs include a first auxiliary-enable switch pair 1104-1 and a second auxiliary-enable switch pair 1104-2. The transceiver controller 214 can control the three switch pairs of the segregated capacitor bank 212 using the switch control signal 324 based on a frequency of a signal being processed by the first transceiver path 306-1.

As shown, the first auxiliary-enable switch pair 1104-1, the auxiliary capacitor Ca, and the second auxiliary-enable switch pair 1104-2 are coupled together in series along an “upper half” part of the segregated capacitor bank 212 between the first plus and minus nodes 610-1 and 612-1 and the plus and minus differential nodes 328 and 330. For a relatively higher frequency portion of the first frequency band 332-1, the switches of the main-enable switch pair 1102 are closed, but the switches of both of the first auxiliary-enable switch pair 1104-1 and the second auxiliary-enable switch pair 1104-2 are open. This protects the first transformer 302-1 from the parasitic capacitance of the auxiliary capacitor Ca. However, for a relatively lower frequency portion of the first frequency band 332-1, the switches of both of the first auxiliary-enable switch pair 1104-1 and the second auxiliary-enable switch pair 1104-2 are also closed. This configuration of the segregated capacitor bank 212 places the main capacitor Cm in parallel with the auxiliary capacitor Ca. The total capacitance of the segregated capacitor bank 212 is therefore increased to tune the first transformer 302-1 for the relatively lower frequency portion of the first frequency band 332-1.

In alternative implementations, the illustrated segregated capacitor bank 212 can be incorporated into the second example implementation of FIGS. 8 to 10-3 (e.g., between the first transformer 302-1 and the first mixer 130-1 in FIG. 9). In such cases, the main-enable switch pair 1102 can be omitted if the associated first transceiver path 306-1 is otherwise activated and deactivated (e.g., by activating or deactivating one or more active components disposed along the associated first transceiver path 306-1). Further, although the segregated capacitor bank 212 is shown being incorporated into the first transceiver path 306-1, a segregated capacitor bank 212 can be incorporated into any one or more transceiver paths of a transceiver path set 300.

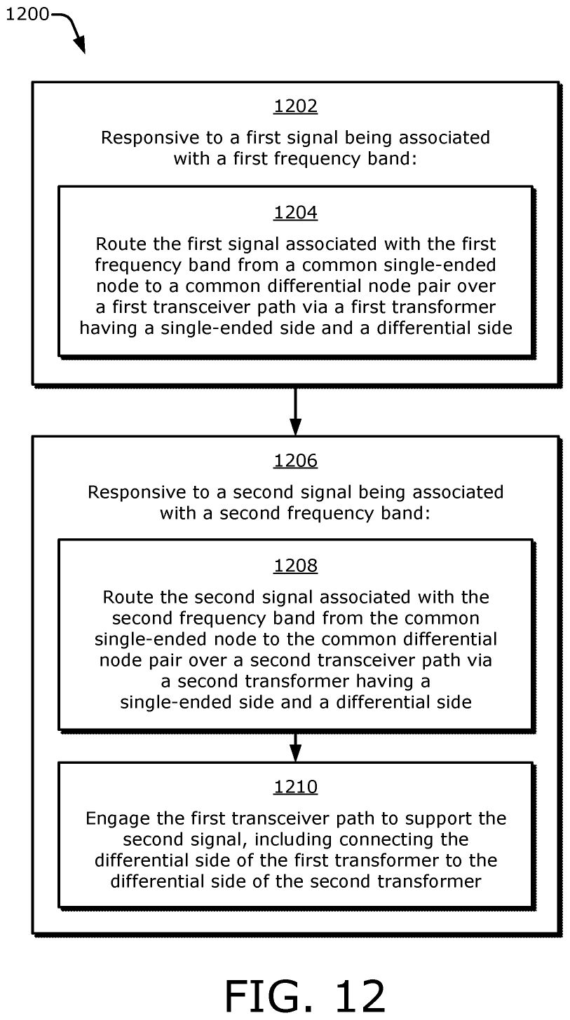

FIG. 12 is a flow diagram illustrating an example process 1200 for operating a wireless transceiver with transformer reconfigurability in accordance with a first implementation. The process 1200 is described in the form of a set of blocks 1202-1210 that specify operations that can be performed. However, operations are not necessarily limited to the order shown in FIG. 12 or described herein, for the operations may be implemented in alternative orders or in fully or partially overlapping manners. Operations represented by the illustrated blocks of the process 1200 may be performed by a wireless transceiver 120 or a portion thereof (e.g., of FIGS. 1 to 3 or 5 to 7-3). More specifically, the operations of the process 1200 may be performed by a set of transformers 124, single-ended switch circuitry 606, differential switch circuitry 126, or a transceiver controller 214.

At block 1202, it can be determined if a first signal is associated with a first frequency band. For example, a transceiver controller 214 may determine if a first signal that is to be processed by a wireless transceiver 120 has a first frequency within a first frequency band 332-1. If so, then the operation(s) of block 1204 are performed. If not, then the operations of the process 1200 continue at block 1206.

At block 1204, the first signal associated with the first frequency band is routed from a common single-ended node to a common differential node pair over a first transceiver path via a first transformer having a single-ended side and a differential side. For example, the transceiver controller 214 can route the first signal associated with the first frequency band 332-1 from a common single-ended node 326-0 to a common differential node pair 320 over a first transceiver path 306-1 via a first transformer 302-1 having a single-ended side 304-1 and a differential side 304-2. This may be performed by closing first, second, and seventh switches 312-1, 312-2, and 312-7, as shown in FIG. 7-1.

At block 1206, it can be determined if a second signal is associated with a second frequency band. For example, the transceiver controller 214 may determine if a second signal that is to be processed by the wireless transceiver 120 has a second frequency within a second frequency band 332-2, such as an upper frequency portion of the second frequency band 332-2. If so, then the operations of blocks 1208 and 1210 are performed.

At block 1208, the second signal associated with the second frequency band is routed from the common single-ended node to the common differential node pair over a second transceiver path via a second transformer having a single-ended side and a differential side. For example, the transceiver controller 214 can route the second signal associated with the second frequency band 332-2 from the common single-ended node 326-0 to the common differential node pair 320 over a second transceiver path 306-2 via a second transformer 302-2 having a single-ended side 304-1 and a differential side 304-2. For instance, the transceiver controller 214 can cause third, fourth, and eighth switches 312-3, 312-4, and 312-8 to close, as shown in FIG. 7-2.

At block 1210, the first transceiver path is engaged to support the second signal, including by connecting the differential side of the first transformer to the differential side of the second transformer. For example, the transceiver controller 214 can engage the first transceiver path 306-1 to support the second signal being processed by the second transceiver path 306-2, including by connecting the differential side 304-2 of the first transformer 302-1 to the differential side 304-2 of the second transformer 302-2. To do so, the transceiver controller 214 can further cause the first and second switches 312-1 and 312-2 to close and cause the seventh switch 312-7 to open, as shown in FIG. 7-2.

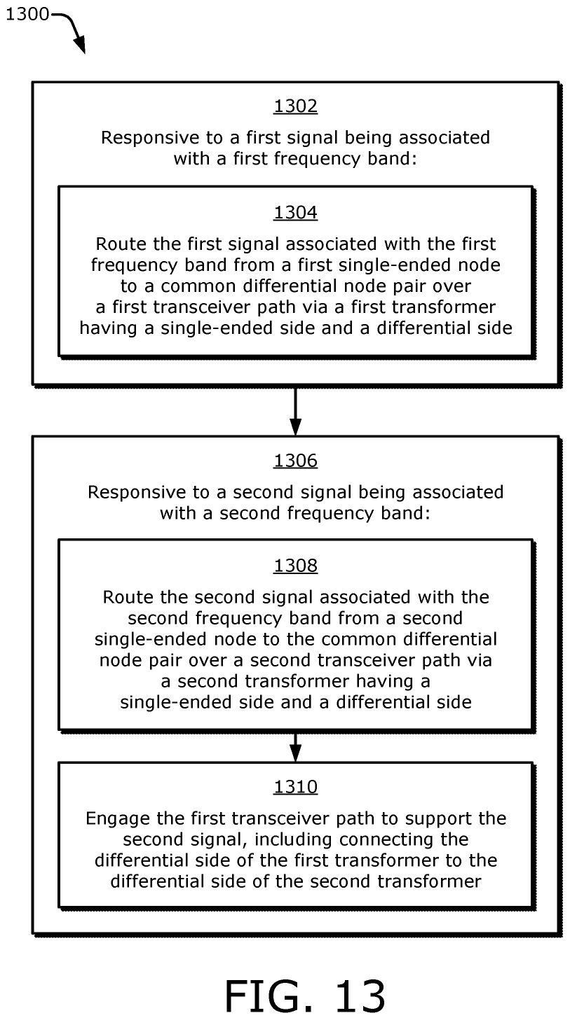

FIG. 13 is a flow diagram illustrating an example process 1300 for operating a wireless transceiver with transformer reconfigurability in accordance with a second implementation. The process 1300 is described in the form of a set of blocks 1302-1310 that specify operations that can be performed. However, operations are not necessarily limited to the order shown in FIG. 13 or described herein, for the operations may be implemented in alternative orders or in fully or partially overlapping manners. Operations represented by the illustrated blocks of the process 1300 may be performed by a wireless transceiver 120 (e.g., of FIGS. 1 to 3 or 8 to 10-3). More specifically, the operations of the process 1300 may be performed by a set of transformers 124, differential switch circuitry 126, or a transceiver controller 214, in conjunction with one or more other narrowband components disposed along a given transceiver path 306.

At block 1302, it can be determined if a first signal is associated with a first frequency band. For example, a transceiver controller 214 may determine if a first signal that is to be processed by a wireless transceiver 120 has a first frequency within a first frequency band 332-1. If so, then the operation(s) of block 1304 are performed. If not, then the operations of the process 1300 continue at block 1306.

At block 1304, the first signal associated with the first frequency band is routed from a first single-ended node to a common differential node pair over a first transceiver path via a first transformer having a single-ended side and a differential side. For example, the transceiver controller 214 can route the first signal associated with the first frequency band 332-1 from a first single-ended node 326-1 to a common differential node pair 320 over a first transceiver path 306-1 via a first transformer 302-1 having a single-ended side 304-1 and a differential side 304-2. This routing may be performed by activating an active component coupled along the first transceiver path 306-1 (e.g., a first single-ended amplifier 122-1 or a first mixer 130-1, including both, as shown in FIG. 10-1 with “check” marks) or by closing as few as a single switch or a single switch pair disposed in series along the first transceiver path 306-1.

At block 1306, it can be determined if a second signal is associated with a second frequency band. For example, the transceiver controller 214 may determine if a second signal that is to be processed by the wireless transceiver 120 has a second frequency within a second frequency band 332-2, such as an upper frequency portion thereof. If so, then the operations of blocks 1308 and 1310 are performed.

At block 1308, the second signal associated with the second frequency band is routed from a second single-ended node to the common differential node pair over a second transceiver path via a second transformer having a single-ended side and a differential side. For example, the transceiver controller 214 can route the second signal associated with the second frequency band 332-2 from a second single-ended node 326-2 to the common differential node pair 320 over a second transceiver path 306-2 via a second transformer 302-2 having a single-ended side 304-1 and a differential side 304-2. For instance, the second signal can be routed from the second single-ended node 326-2 to the common differential node pair 320 over the second transceiver path 306-2 via a second single-ended amplifier 122-2 and a second mixer 130-2, with the second mixer 130-2 coupled between the second transformer 302-2 and the common differential node pair 320, as shown in FIG. 10-2.

At block 1310, the first transceiver path is engaged to support the second signal, including by connecting the differential side of the first transformer to the differential side of the second transformer. For example, the transceiver controller 214 can engage the first transceiver path 306-1 to support the second signal being processed by the second transceiver path 306-2, including by connecting the differential side 304-2 of the first transformer 302-1 to the differential side 304-2 of the second transformer 302-2. To do so, the transceiver controller 214 may close first and second switches 312-1 and 312-2 of a first switch pair 322-1 (each of FIG. 10-2) that are coupled between the second inductor L2 of the first transformer 302-1 and the second inductor L2 of the second transformer 302-2. The first switch pair 322-1 may be functionally separate from circuit structure that activates or deactivates the first transceiver path 306-1 or the second transceiver path 306-2.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Further, items represented in the accompanying figures and terms discussed herein may be indicative of one or more items or terms, and thus reference may be made interchangeably to single or plural forms of the items and terms in this written description. Finally, although subject matter has been described in language specific to structural features or methodological operations, it is to be understood that the subject matter defined in the appended claims is not necessarily limited to the specific features or operations described above, including not necessarily being limited to the organizations in which features are arranged or the orders in which operations are performed.

What is claimed is:

1. An apparatus for transformer reconfigurability, the apparatus comprising:
a common single-ended node;
a common differential node pair;
a transceiver path set including:
a first transceiver path comprising a first single-ended interface and a first differential interface, the first transceiver path including a first transformer; and
a second transceiver path comprising a second single-ended interface and a second differential interface, the second transceiver path including a second transformer;
single-ended switch circuitry coupled between each transceiver path of the transceiver path set and the common single-ended node; and
differential switch circuitry coupled between each transceiver path of the transceiver path set and the common differential node pair.

2. The apparatus of claim 1, further comprising:
a transceiver controller coupled to the differential switch circuitry, the transceiver controller configured to cause the differential switch circuitry to selectively connect the first transformer in parallel with the second transformer responsive to a frequency of a signal being processed by the transceiver path set.

3. The apparatus of claim 1, wherein:
the first transformer includes a single-ended side and a differential side, the single-ended side coupled to the first single-ended interface and the differential side coupled to the first differential interface;
the second transformer includes a single-ended side and a differential side, the single-ended side coupled to the second single-ended interface and the differential side coupled to the second differential interface;
the single-ended switch circuitry is configured to selectively connect at least one of the single-ended side of the first transformer or the single-ended side of the second transformer to the common single-ended node; and
the differential switch circuitry is configured to selectively connect at least one of the differential side of the first transformer or the differential side of the second transformer to the common differential node pair.

4. The apparatus of claim 3, further comprising:
a transceiver controller coupled to the single-ended switch circuitry and the differential switch circuitry, wherein:
the first transceiver path corresponds to a first frequency band, and the second transceiver path corresponds to a second frequency band; and
responsive to a signal having a frequency within the second frequency band, the transceiver controller is configured to:
activate the second transceiver path to process the signal; and
engage the first transceiver path to extend a tuning range associated with the second transceiver path.

5. The apparatus of claim 4, wherein responsive to the signal having the frequency within the second frequency band, the transceiver controller is configured to:
connect the single-ended side of the second transformer to the common single-ended node using the single-ended switch circuitry and connect the differential side of the second transformer to the common differential node pair using the differential switch circuitry to activate the second transceiver path; and
connect the differential side of the first transformer to the differential side of the second transformer via the common differential node pair using the differential switch circuitry to engage the first transceiver path.

6. The apparatus of claim 1, wherein the single-ended switch circuitry includes:
a first switch coupled between the common single-ended node and the first single-ended interface; and
a second switch coupled between the common single-ended node and the second single-ended interface.

7. The apparatus of claim 6, wherein:
the transceiver path set includes a third transceiver path comprising a third single-ended interface and a third differential interface, the third transceiver path including a third transformer; and
the single-ended switch circuitry includes a third switch coupled between the common single-ended node and the third single-ended interface.

8. The apparatus of claim 6, further comprising:
an amplifier including a first node and a second node, the second node coupled to the common single-ended node; and
at least one antenna coupled to the first node of the amplifier.

9. The apparatus of claim 8, wherein:
the amplifier comprises a single-ended low-noise amplifier including an amplifier input and an amplifier output;
the amplifier input of the single-ended low-noise amplifier corresponds to the first node that is coupled to the at least one antenna; and
the amplifier output of the single-ended low-noise amplifier corresponds to the second node that is coupled to the common single-ended node.

10. The apparatus of claim 8, further comprising:
a differential transceiver component coupled to the common differential node pair,
wherein the differential transceiver component comprises at least one of a differential amplifier, a differential mixer, or a differential filter.

11. The apparatus of claim 6, wherein the differential switch circuitry includes:
a first switch pair coupled between the first differential interface and the common differential node pair; and
a second switch pair coupled between the second differential interface and the common differential node pair.

12. The apparatus of claim 11, wherein:
the first transformer is coupled between the first single-ended interface and the first differential interface, the first transformer configured as a first balun to convert between a single-ended signaling format and a differential signaling format; and
the second transformer is coupled between the second single-ended interface and the second differential interface, the second transformer configured as a second balun to convert between the single-ended signaling format and the differential signaling format.

13. The apparatus of claim 1, further comprising:
a transceiver controller coupled to the differential switch circuitry, wherein:
the first transformer includes a first inductor corresponding to the first differential interface;
the second transformer includes a second inductor corresponding to the second differential interface; and
responsive to a signal having a frequency corresponding to the second transceiver path, the transceiver controller is configured to control the differential switch circuitry to increase a self-resonant frequency of the second inductor using the first inductor.

14. A method for operating a wireless transceiver with transformer reconfigurability, the method comprising:
responsive to a first signal being associated with a first frequency band,
routing the first signal associated with the first frequency band from a common single-ended node to a common differential node pair over a first transceiver path via a first transformer having a single-ended side and a differential side; and
responsive to a second signal being associated with a second frequency band,
routing the second signal associated with the second frequency band from the common single-ended node to the common differential node pair over a second transceiver path via a second transformer having a single-ended side and a differential side; and
engaging the first transceiver path to support the second signal, including connecting the differential side of the first transformer to the differential side of the second transformer.

15. The method of claim 14, further comprising:
responsive to a third signal being associated with a third frequency band,
routing the third signal associated with the third frequency band from the common single-ended node to the common differential node pair over a third transceiver path via a third transformer having a single-ended side and a differential side; and
engaging the second transceiver path to support the third signal, including connecting the differential side of the second transformer to the differential side of the third transformer.

16. The method of claim 15, wherein the routing of the third signal associated with the third frequency band comprises:
disconnecting the single-ended side of the first transformer from the common single-ended node;
disconnecting the differential side of the first transformer from the common differential node pair; and
disconnecting the single-ended side of the second transformer from the common single-ended node.

17. The method of claim 14, wherein the routing of the first signal associated with the first frequency band comprises:
connecting the single-ended side of the first transformer to the common single-ended node; and
connecting the differential side of the first transformer to the common differential node pair.

18. The method of claim 14, wherein:
the routing of the second signal associated with the second frequency band comprises:
disconnecting the single-ended side of the first transformer from the common single-ended node;
connecting the single-ended side of the second transformer to the common single-ended node; and
connecting the differential side of the second transformer to the common differential node pair; and
the engaging of the first transceiver path to support the second signal comprises connecting the differential side of the first transformer to the common differential node pair.

19. The method of claim 14, wherein the engaging the first transceiver path to support the second signal comprises increasing a self-resonant frequency of an inductance corresponding to the differential side of the second transformer using an inductor at the differential side of the first transformer.

20. An apparatus for transformer reconfigurability, the apparatus comprising:
multiple single-ended nodes including a first single-ended node and a second single-ended node;
a common differential node pair;
a transceiver path set including:
a first transceiver path comprising a first single-ended interface coupled to the first single-ended node and a first differential interface coupled to the common differential node pair, the first transceiver path including a first transformer; and
a second transceiver path comprising a second single-ended interface coupled to the second single-ended node and a second differential interface coupled to the common differential node pair, the second transceiver path including a second transformer; and
differential switch circuitry coupled between the first transformer and the second transformer.

21. The apparatus of claim 20, wherein:
the first transformer includes a single-ended side and a differential side;
the second transformer includes a single-ended side and a differential side; and
the differential switch circuitry includes a first switch pair coupled between the differential side of the first transformer and the differential side of the second transformer.

22. The apparatus of claim 21, wherein:
the differential side of the first transformer comprises at least one inductor having a first plus node and a first minus node;
the differential side of the second transformer comprises at least one other inductor having a second plus node and a second minus node; and
the first switch pair comprises:
a first switch coupled between the first plus node and the second minus node; and
a second switch coupled between first minus node and the second plus node.

23. The apparatus of claim 21, wherein:
the multiple single-ended nodes include a third single-ended node;
the transceiver path set includes a third transceiver path comprising a third single-ended interface coupled to the third single-ended node and a third differential interface coupled to the common differential node pair, the third transceiver path including a third transformer;
the third transformer includes a single-ended side and a differential side; and
the differential switch circuitry includes a second switch pair coupled between the differential side of the second transformer and the differential side of the third transformer.

24. The apparatus of claim 21, further comprising:
multiple antennas respectively coupled to the multiple single-ended nodes; and
a differential transceiver component coupled to the common differential node pair, the differential transceiver component comprising at least one of a differential amplifier or a differential filter,
wherein the transceiver path set comprises a multiple-input, single-output (MISO) section of a wireless transceiver.

25. The apparatus of claim 21, wherein:
the first transceiver path includes a first single-ended amplifier coupled between the first single-ended node and the single-ended side of the first transformer; and
the second transceiver path includes a second single-ended amplifier coupled between the second single-ended node and the single-ended side of the second transformer.

26. The apparatus of claim 25, wherein:
the first transceiver path includes a first mixer coupled between the differential side of the first transformer and the common differential node pair; and
the second transceiver path includes a second mixer coupled between the differential side of the second transformer and the common differential node pair.

27. The apparatus of claim 21, further comprising:
a transceiver controller coupled to the differential switch circuitry, wherein:
the first transceiver path corresponds to a first frequency band, and the second transceiver path corresponds to a second frequency band;
responsive to a signal having a frequency within the second frequency band, the transceiver controller is configured to:
route the signal through the second transceiver path to process the signal; and
connect the differential side of the first transformer to the differential side of the second transformer.

28. A method for operating a wireless transceiver with transformer reconfigurability, the method comprising:
responsive to a first signal being associated with a first frequency band,
routing the first signal associated with the first frequency band from a first single-ended node to a common differential node pair over a first transceiver path via a first transformer having a single-ended side and a differential side; and
responsive to a second signal being associated with a second frequency band,
routing the second signal associated with the second frequency band from a second single-ended node to the common differential node pair over a second transceiver path via a second transformer having a single-ended side and a differential side; and
engaging the first transceiver path to support the second signal, including connecting the differential side of the first transformer to the differential side of the second transformer.

29. The method of claim 28, further comprising:
responsive to a third signal being associated with a third frequency band,
routing the third signal associated with the third frequency band from a third single-ended node to the common differential node pair over a third transceiver path via a third transformer having a single-ended side and a differential side; and
engaging the second transceiver path to support the third signal, including connecting the differential side of the second transformer to the differential side of the third transformer.

30. The method of claim 29, wherein:
the routing of the second signal associated with the second frequency band comprises routing the second signal from the second single-ended node to the common differential node pair over the second transceiver path via a second mixer that is coupled between the second transformer and the common differential node pair;
the routing of the third signal associated with the third frequency band comprises routing the third signal from the third single-ended node to the common differential node pair over the third transceiver path via a third mixer that is coupled between the third transformer and the common differential node pair;
the connecting of the differential side of the first transformer to the differential side of the second transformer comprises closing a first switch pair coupled between the differential side of the first transformer and the differential side of the second transformer; and
the connecting of the differential side of the second transformer to the differential side of the third transformer comprises closing a second switch pair coupled between the differential side of the second transformer and the differential side of the third transformer.
